(19) United States
(12) Patent Application Publication
(10) Pub. No.: US 2025/0104210 A1
(43) Pub. Date: Mar. 27, 2025

(54) METHOD AND SYSTEM OF DEFECT DETECTION FOR INSPECTION SAMPLE BASED ON MACHINE LEARNING MODEL

(71) Applicant: ASML Netherlands B.V., Veldhoven (NL)

(72) Inventors: Lingling PU, San Jose, CA (US); Hongquan ZUO, San Jose, CA (US)

(73) Assignee: ASML Netherlands B.V., Veldhoven (NL)

(21) Appl. No.: 18/716,123

(22) PCT Filed: Nov. 18, 2022
(86) PCT No.: PCT/EP2022/082360

§ 371 Date: Jun. 3, 2024

Related U.S. Application Data
(60) Provisional application No. 63/290,601, filed on Dec. 16, 2021.

(51) Int. Cl. G06T 7/00; G06N 3/0455

(52) U.S. Cl. CPC G06T 7/0004; G06N 3/0455; G06T 2207/20081; G06T 2207/30148

(57) ABSTRACT

Systems and methods for training a machine learning model for defect detection include obtaining training data including an inspection image of a fabricated integrated circuit (IC) and design layout data of the IC, and training a machine learning model using the training data. The machine learning model includes a first autoencoder and a second autoencoder. The first autoencoder includes a first encoder and a first decoder. The second autoencoder includes a second encoder and a second decoder. The second decoder is configured to obtain a first code outputted by the first encoder. The first decoder is configured to obtain a second code outputted by the second encoder.

### CROSS-REFERENCE TO RELATED APPLICATIONS

This application claims priority of U.S. application 63/290,601 which was filed on 16 Dec. 2021 and which is incorporated herein in its entirety by reference.

### FIELD

The description herein relates to the field of image inspection apparatus, and more particularly to defect detection for inspection samples based on machine learning models.

### BACKGROUND

An image inspection apparatus (e.g., a charged-particle beam apparatus or an optical beam apparatus) is able to produce a two-dimensional (2D) image of a wafer substrate by detecting particles (e.g., photons, secondary electrons, backscattered electrons, mirror electrons, or other kinds of electrons) from a surface of a wafer substrate upon impingement by a beam (e.g., a charged-particle beam or an optical beam) generated by a source associated with the inspection apparatus. Various image inspection apparatuses are used on semiconductor wafers in semiconductor industry for various purposes such as wafer processing (e.g., e-beam direct write lithography system), process monitoring (e.g., critical dimension scanning electron microscope (CD-SEM)), wafer inspection (e.g., e-beam inspection system), or defect analysis (e.g., defect review SEM, or say DR-SEM and Focused Ion Beam system, or say FIB).

To control quality of a manufactured structures on the wafer substrate, the 2D image of the wafer substrate may be analyzed to detect potential defects in the wafer substrate. In some applications, a 2D image of a die of the wafer substrate may be compared with a 2D image of another die (e.g., a neighboring die) of the wafer substrate for defect detection, which may be referred to as a die-to-die (“D2D”) inspection. In some applications, a 2D image of a die of the wafer substrate may be compared with a 2D rendered image of a design layout of the die (e.g., a graphic design system or “GDS” layout) for defect detection, which may be referred to as a die-to-database (“D2DB”) inspection. In some applications, a 2D image of a die of the wafer substrate may be compared with a simulation image of the die. The simulation image may be generated by a simulation technique configured to simulate an image measured by the image inspection apparatus, using the design layout of the die as input. The sensitivity to noise of the defect inspection methods may be an important factor for both performance, cost, and accuracy of those applications.

### SUMMARY

Embodiments of the present disclosure provide systems and methods of training a machine learning model for defect detection, systems and methods of training a plurality of machine learning models for defect detection, and systems and methods of defect detection. In some embodiments, a non-transitory computer-readable medium may store a set of instructions that is executable by at least one processor of an apparatus to cause the apparatus to perform a method. The method may include obtaining training data including an inspection image of a fabricated integrated circuit (IC) and design layout data of the IC. The method may also include training a machine learning model using the training data. The machine learning model may include a first autoencoder and a second autoencoder. The first autoencoder may include a first encoder and a first decoder. The second autoencoder may include a second encoder and a second decoder. The second decoder may be configured to obtain a first code outputted by the first encoder. The first decoder may be configured to obtain a second code outputted by the second encoder.

In some embodiments, a non-transitory computer-readable medium may store a set of instructions that is executable by at least one processor of an apparatus to cause the apparatus to perform a method. The method may include obtaining first data including a first inspection image of a fabricated first integrated circuit (IC) and first design layout data of the first IC. The method may also include training a first machine learning model using the first data. The method may further include obtaining second data including a second inspection image of a fabricated second IC and second design layout data of the second IC. The method may further include generating adjusted design layout data by adjusting a polygon of the second design layout data. The method may further include training a second machine learning model using the second inspection image and the adjusted design layout data.

In some embodiments, a non-transitory computer-readable medium may store a set of instructions that is executable by at least one processor of an apparatus to cause the apparatus to perform a method. The method may include obtaining an inspection image of a fabricated integrated circuit (IC) and design layout data of the IC. The method may also include inputting the inspection image and the design layout data to a trained machine learning model to generate a defect map, wherein the trained machine learning model includes a first cross autoencoder, and the first cross autoencoder includes a first autoencoder configured to obtain the inspection image as input and a second autoencoder configured to obtain the design layout data as input. The method may further include detecting a potential defect in the inspection image based on the defect map.

In some embodiments, a system may include an image inspection apparatus configured to scan a sample and generate an inspection image of an integrated circuit (IC) fabricated on the sample, and a controller including circuitry. The controller may be configured to obtain training data including the inspection image of the IC and design layout data of the IC. The controller may be further configured to train a machine learning model using the training data. The machine learning model may include a first autoencoder and a second autoencoder. The first autoencoder may include a first encoder and a first decoder. The second autoencoder may include a second encoder and a second decoder. The second decoder may be configured to obtain a first code outputted by the first encoder. The first decoder may be configured to obtain a second code outputted by the second encoder.

In some embodiments, a system may include an image inspection apparatus configured to scan a sample and generate an inspection image of an integrated circuit (IC) fabricated on the sample, and a controller including circuitry. The controller may be configured to obtain first data including a first inspection image of a fabricated first IC and first design layout data of the first IC. The controller may also be configured to train a first machine learning model using the first data. The controller may further be configured to obtain second data including a second inspection image of a fabricated second IC and second design layout data of the second IC. The controller may further be configured to generate adjusted design layout data by adjusting a polygon of the second design layout data. The controller may further be configured to train a second machine learning model using the second inspection image and the adjusted design layout data.

In some embodiments, a system may include an image inspection apparatus configured to scan a sample and generate an inspection image of an integrated circuit (IC) fabricated on the sample, and a controller including circuitry. The controller may be configured to obtain the inspection image of the IC and design layout data of the IC. The controller may also be configured to input the inspection image and the design layout data to a trained machine learning model to generate a defect map, wherein the trained machine learning model includes a first cross autoencoder, and the first cross autoencoder includes a first autoencoder configured to obtain the inspection image as input and a second autoencoder configured to obtain the design layout data as input. The controller may further be configured to detect a potential defect in the inspection image based on the defect map.

In some embodiments, a computer-implemented method of training a machine learning model for defect detection may include obtaining training data including an inspection image of a fabricated integrated circuit (IC) and design layout data of the IC. The method may also include training a machine learning model using the training data. The machine learning model may include a first autoencoder and a second autoencoder. The first autoencoder may include a first encoder and a first decoder. The second autoencoder may include a second encoder and a second decoder. The second decoder may be configured to obtain a first code outputted by the first encoder. The first decoder may be configured to obtain a second code outputted by the second encoder.

In some embodiments, a computer-implemented method of training a plurality of machine learning models for defect detection may include obtaining first data including a first inspection image of a fabricated first integrated circuit (IC) and first design layout data of the first IC. The method may also include training a first machine learning model using the first data. The method may further include obtaining second data including a second inspection image of a fabricated second IC and second design layout data of the second IC. The method may further include generating adjusted design layout data by adjusting a polygon of the second design layout data. The method may further include training a second machine learning model using the second inspection image and the adjusted design layout data.

In some embodiments, a computer-implemented method of defect detection may include obtaining an inspection image of a fabricated integrated circuit (IC) and design layout data of the IC.

The method may also include inputting the inspection image and the design layout data to a trained machine learning model to generate a defect map, wherein the trained machine learning model includes a first cross autoencoder, and the first cross autoencoder includes a first autoencoder configured to obtain the inspection image as input and a second autoencoder configured to obtain the design layout data as input. The method may further include detecting a potential defect in the inspection image based on the defect map.

### BRIEF DESCRIPTION OF THE DRAWINGS

FIG. 1 is a schematic diagram illustrating an example charged-particle beam inspection (CPBI) system, consistent with some embodiments of the present disclosure.

FIG. 2 is a schematic diagram illustrating an example charged-particle beam tool, consistent with some embodiments of the present disclosure that may be a part of the example charged-particle beam inspection system of FIG. 1.

FIG. 3 is a schematic diagram illustrating an example neural network, consistent with some embodiments of the present disclosure.

FIG. 4 is a schematic diagram illustrating an example autoencoder, consistent with some embodiments of the present disclosure.

FIG. 5 is a schematic diagram illustrating an example cross autoencoder, consistent with some embodiments of the present disclosure.

FIG. 6 is a flowchart illustrating an example method for training a machine learning model for defect detection, consistent with some embodiments of the present disclosure.

FIG. 7 is a schematic diagram illustrating two example machine learning models for training, consistent with some embodiments of the present disclosure.

FIG. 8 is a flowchart illustrating an example method for training a plurality of machine learning models for defect detection, consistent with some embodiments of the present disclosure.

FIG. 9A illustrates an example inspection image of a fabricated integrated circuit, consistent with some embodiments of the present disclosure.

FIG. 9B illustrates an example rendered image of the integrated circuit of FIG. 9A, consistent with some embodiments of the present disclosure.

FIG. 9C illustrates an example defect map generated using the inspection image of FIG. 9A and the rendered image of FIG. 9B, consistent with some embodiments of the present disclosure.

FIG. 10 is a schematic diagram illustrating a defect detection process using a trained machine learning model, consistent with some embodiments of the present disclosure.

FIG. 11 is a flowchart illustrating an example method for defect detection, consistent with some embodiments of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the subject matter recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them may be fit on the substrate. For example, an IC chip in a smartphone may be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection may be carried out using a scanning charged-particle microscope (“SCPM”). For example, an SCPM may be a scanning electron microscope (SEM). A SCPM may be used to image these extremely small structures, in effect, taking a “picture” of the structures of the wafer. The image may be used to determine if the structure was formed properly in the proper location. If the structure is defective, then the process may be adjusted, so the defect is less likely to recur.

The working principle of a SCPM (e.g., a SEM) is similar to a camera. A camera takes a picture by receiving and recording intensity of light reflected or emitted from people or objects. An SCPM takes a “picture” by receiving and recording energies or quantities of charged particles (e.g., electrons) reflected or emitted from the structures of the wafer. Typically, the structures are made on a substrate (e.g., a silicon substrate) that is placed on a platform, referred to as a stage, for imaging. Before taking such a “picture,” a charged-particle beam may be projected onto the structures, and when the charged particles are reflected or emitted (“exiting”) from the structures (e.g., from the wafer surface, from the structures underneath the wafer surface, or both), a detector of the SCPM may receive and record the energies or quantities of those charged particles to generate an inspection image. To take such a “picture,” the charged-particle beam may scan through the wafer (e.g., in a line-by-line or zig-zag manner), and the detector may receive exiting charged particles coming from a region under charged particle-beam projection (referred to as a “beam spot”). The detector may receive and record exiting charged particles from each beam spot one at a time and join the information recorded for all the beam spots to generate the inspection image. Some SCPMs use a single charged-particle beam (referred to as a “single-beam SCPM,” such as a single-beam SEM) to take a single “picture” to generate the inspection image, while some SCPMs use multiple charged-particle beams (referred to as a “multi-beam SCPM,” such as a multi-beam SEM) to take multiple “sub-pictures” of the wafer in parallel and stitch them together to generate the inspection image. By using multiple charged-particle beams, the SEM may provide more charged-particle beams onto the structures for obtaining these multiple “sub-pictures,” resulting in more charged particles exiting from the structures. Accordingly, the detector may receive more exiting charged particles simultaneously and generate inspection images of the structures of the wafer with higher efficiency and faster speed.

Wafer defect detection is a critical step for semiconductor volume production and process development in research and development phase. A wafer may include one or more dies. A die, as used herein, refers to a portion or block of wafer on which an integrated circuit may be fabricated. Typically, integrated circuits of the same design may be fabricated in batches on a single wafer of semiconductor, and then the wafer may be cut (or referred to as “diced”) into pieces, each piece including one copy of the integrated circuits and being referred to as a die. Several conventional techniques exist for wafer defect detection, including die-to-die (“D2D”) inspection technique, die-to-database (“D2DB”) inspection technique, and simulation-based inspection technique.

In the D2D inspection technique, for each of the dies on the wafer, an inspection image of the die (referred to as a “die inspection image”) may be generated. For example, the die inspection image may be an actually measured SEM image. The die inspection images may be compared and analyzed against each other for defect detection. For example, each pixel of a first die inspection image of a first die may be compared with each corresponding pixel of a second die inspection image of a second die to determine a difference in their gray-level values. Potential defects may be identified based on the pixel-wise gray-level value differences. For example, if one or more of the differences exceed a predetermined threshold, the pixels in at least one of the first die inspection image or the second die inspection image corresponding to the one of more of the differences may represent a part of a potential defect. In some embodiments, the die inspection images under comparison (e.g., the first die inspection image or the second die inspection image) may be associated with neighboring dies (e.g., the first die and the second die are randomly selected from dies being separated by less than four dies). In some embodiments, the die inspection images under comparison (e.g., the first die inspection image or the second die inspection image) may be associated with shifted-period dies (e.g., the first die and the second die are selected from dies being separated by a fixed number of dies).

In the D2DB inspection technique, a die inspection image of a die on the wafer may be compared with a rendered image generated from a design layout file (e.g., a GDS layout file) of the same die. The design layout file may include non-visual description of the integrated circuit in the die, and the rendering of the design layout file may refer to visualization (e.g., a 2D image) of the non-visual description. For example, the die inspection image may be compared with the rendered image to determine a difference in one or more of their corresponding features, such as, for example, pixel-wise gray-level values, gray-level intensity inside a polygon, or a distance between corresponding patterns. Potential defects may be identified based on the differences. For example, if one or more of the differences exceed a predetermined threshold, the pixels in the die inspection image corresponding to the one of more of the differences may represent a part of a potential defect.

In the simulation-based inspection technique, a die inspection image may be compared with a simulation image (e.g., a simulated SEM image) corresponding to the inspection image. In some embodiments, the simulation image may be generated by a machine learning model (e.g., a generative adversarial network or “GAN”) for simulating graphical representations of inspection images measured by the image inspection apparatus. The simulation image may be used as a reference to be compared with the die inspection image. For example, each pixel of the die inspection image may be compared with each corresponding pixel of the simulation image to determine a difference in their gray-level values. Potential defects may be identified based on the pixel-wise gray-level value differences. For example, if one or more of the differences exceed a predetermined threshold, the pixels in the die inspection image corresponding to the one of more of the differences may represent a part of a potential defect.

However, the existing techniques for wafer defect detection may face some challenges. For example, the pixel-wise gray-level value comparison in the D2D inspection technique may be sensitive to various factors, such as, for example, image noise, physical effects (e.g., charging effects) incurred in image generation, or image distortion. Also, the D2D inspection technique cannot be applied to a wafer that includes a single die because there can be only one die inspection image generated and no other die inspection image for the comparison. As another example, the comparison in the D2DB inspection technique may be sensitive to alignment accuracy between the die inspection image and the rendered image (or referred to as “image-to-GDS alignment accuracy”). In another example, differences between the die inspection image and the simulation image in the simulation-based inspection technique may be larger than those in the D2D inspection technique and the D2DB inspection technique, in terms of image noise level, image noise distribution, gray-level histogram, or local charging. Such larger differences may introduce high nuisance rate in the pixel-wise gray-level value comparison in the simulation-based inspection technique. Alternatively, to reduce the above-described nuisance rate in the simulation-based inspection technique, the simulation-based inspection technique may consume more computation resources than the D2D inspection technique and the D2DB inspection technique.

Embodiments of the present disclosure may provide methods, apparatuses, and systems for defect detection using a trained machine learning model that uses die inspection images and their corresponding rendered images (e.g., generated based on design layout files) as input. The trained machine learning model may include one or more paired autoencoder models (each model pair being referred to as a “cross autoencoder model,” “cross autoencoder,” or “XAE” herein). In some disclosed embodiments, a cross autoencoder may include a first autoencoder and a second autoencoder and may be trained using corresponding die inspection images (e.g., inputted to the first autoencoder) and rendered images (e.g., inputted to the second autoencoder). The cross autoencoder may include a loss function that may include a component representing a difference between a first code outputted by a first encoder of the first autoencoder and a second code outputted by a second encoder of the second autoencoder. In some embodiments, the machine learning model may include multiple cross autoencoders, each cross autoencoder including a pair of autoencoders. The multiple cross autoencoders may be trained independently using different sets of corresponding die inspection images and rendered images. In some embodiments, for defect detection, an inspection image of a fabricated integrated circuit and its corresponding design layout data may be inputted to the trained machine learning model that includes one or more cross autoencoders to generate a defect map. A potential defect in the inspection image may be detected based on the defect map.

Compared with existing techniques for wafer defect detection, the disclosed technical solutions herein provide various technical benefits. For example, by using cross autoencoders in the trained machine learning model, feature extraction and feature comparison may be conducted in a single step for both inspection images and corresponding rendered images generated from design layout data, which may enable generating a defect map for defect detection with higher accuracy and higher efficiency. Also, the cross autoencoders may be trained using either supervised or unsupervised learning, in which the unsupervised learning training may reduce the time and costs for labeling reference data compared with supervised learning, and the supervised learning training may amplify sensitivity of defect-of-interest for the trained cross encoders. Further, when the machine learning model may include multiple cross autoencoders, each of the cross autoencoders may be trained to tackle a specific nuisance-causing problem, and the same inspection image and its corresponding design layout data may be inputted to each of the trained cross autoencoders to generate different output data that may be combined to generate a defect map with lower noise and higher sensitivity to defects. Moreover, the trained machine learning model does not use any simulation image (e.g., as in the above-described simulation-based technique) for defect detection, which may reduce computational resources, costs, and time.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

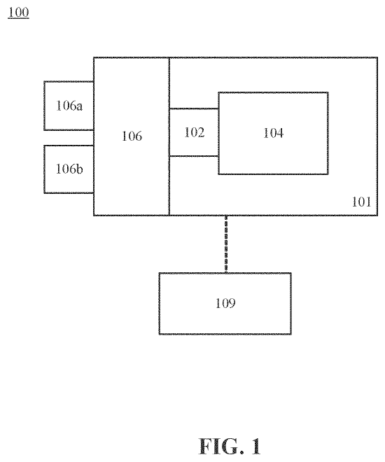

FIG. 1 illustrates an exemplary charged-particle beam inspection (CPBI) system 100 consistent with some embodiments of the present disclosure. CPBI system 100 may be used for imaging. For example, CPBI system 100 may use an electron beam for imaging. As shown in FIG. 1, CPBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer that may execute various controls of CPBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

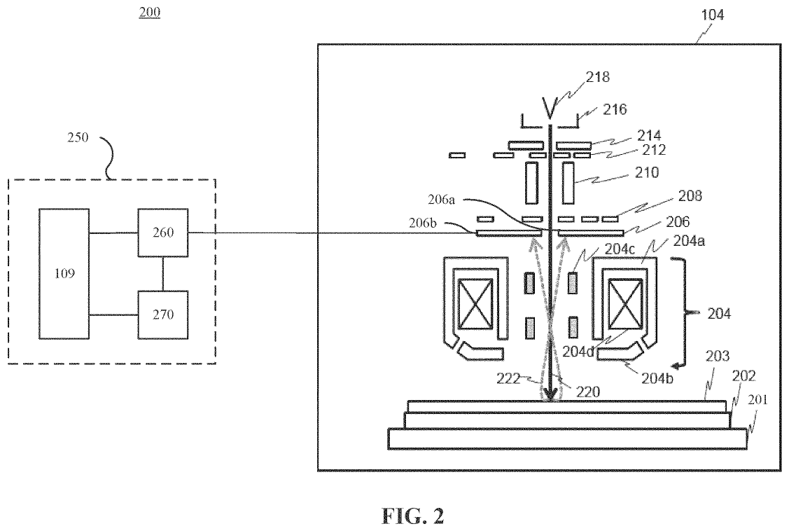

FIG. 2 illustrates an example imaging system 200 according to embodiments of the present disclosure. Beam tool 104 of FIG. 2 may be configured for use in CPBI system 100. Beam tool 104 may be a single beam apparatus or a multi-beam apparatus. As shown in FIG. 2, beam tool 104 includes a motorized sample stage 201, and a wafer holder 202 supported by motorized sample stage 201 to hold a wafer 203 to be inspected. Beam tool 104 further includes an objective lens assembly 204, a charged-particle detector 206 (which includes charged-particle sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Beam tool 104 may additionally include an Energy Dispersive X-ray Spectrometer (EDS) detector (not shown) to characterize the materials on wafer 203.

A primary charged-particle beam 220 (or simply “primary beam 220”), such as an electron beam, is emitted from cathode 218 by applying an acceleration voltage between anode 216 and cathode 218. Primary beam 220 passes through gun aperture 214 and beam limit aperture 212, both of which may determine the size of charged-particle beam entering condenser lens 210, which resides below beam limit aperture 212. Condenser lens 210 focuses primary beam 220 before the beam enters objective aperture 208 to set the size of the charged-particle beam before entering objective lens assembly 204. Deflector 204c deflects primary beam 220 to facilitate beam scanning on the wafer. For example, in a scanning process, deflector 204c may be controlled to deflect primary beam 220 sequentially onto different locations of top surface of wafer 203 at different time points, to provide data for image reconstruction for different parts of wafer 203. Moreover, deflector 204c may also be controlled to deflect primary beam 220 onto different sides of wafer 203 at a particular location, at different time points, to provide data for stereo image reconstruction of the wafer structure at that location. Further, in some embodiments, anode 216 and cathode 218 may generate multiple primary beams 220, and beam tool 104 may include a plurality of deflectors 204c to project the multiple primary beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary beam 220 may be immersed in the magnetic field and may be electrically charged, which, in turn, creates an electric field. The electric field reduces the energy of impinging primary beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary charged-particle beam 222 (or “secondary beam 222”), such as secondary electron beams, may be emitted from the part of wafer 203 upon receiving primary beam 220. Secondary beam 222 may form a beam spot on sensor surfaces 206a and 206b of charged-particle detector 206. Charged-particle detector 206 may generate a signal (e.g., a voltage, a current, or the like.) that represents an intensity of the beam spot and provide the signal to an image processing system 250. The intensity of secondary beam 222, and the resultant beam spot, may vary according to the external or internal structure of wafer 203. Moreover, as discussed above, primary beam 220 may be projected onto different locations of the top surface of the wafer or different sides of the wafer at a particular location, to generate secondary beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on motorized sample stage 201 and includes beam tool 104, as discussed above. Imaging system 200 may also include an image processing system 250 that includes an image acquirer 260, storage 270, and controller 109. Image acquirer 260 may include one or more processors. For example, image acquirer 260 may include a computer, server, mainframe host, terminals, personal computer, any kind of mobile computing devices, and the like, or a combination thereof. Image acquirer 260 may connect with a detector 206 of beam tool 104 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may perform adjustments of brightness and contrast, or the like. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, post-processed images, or other images assisting of the processing. Image acquirer 260 and storage 270 may be connected to controller 109. In some embodiments, image acquirer 260, storage 270, and controller 109 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image including a plurality of imaging areas. The single image may be stored in storage 270. The single image may be an original image that may be divided into a plurality of regions. Each of the regions may include one imaging area containing a feature of wafer 203.

Consistent with some embodiments of this disclosure, a computer-implemented method of training a machine learning model for defect detection may include obtaining training data that includes an inspection image of a fabricated integrated circuit (IC) and design layout data of the IC. The obtaining operation, as used herein, may refer to accepting, taking in, admitting, gaining, acquiring, retrieving, receiving, reading, accessing, collecting, or any operation for inputting data. An inspection image, as used herein, may refer to an image generated as a result of an inspection process performed by a charged-particle inspection apparatus (e.g., system 100 of FIG. 1 or system 200 of FIG. 2). For example, an inspection image may be a SEM image generated by image processing system 250 in FIG. 2. A fabricated IC in this disclosure may refer to an IC manufactured on a sample (e.g., a wafer) in a semiconductor manufacturing process (e.g., a photolithography process). For example, the fabricated IC may be manufactured in a die of the sample. Design layout data of an IC, as used herein, may refer to data representing a designed layout of the IC. In some embodiments, the design layout data may include a design layout file in a GDS format (e.g., a GDS layout file). The design layout file may be visualized (also referred to as “rendered”) to be a 2D image (referred to as a “rendered image” herein) that presents the layout of the IC. The rendered image may include various geometric features (e.g., vertices, edges, corners, polygons, holes, bridges, vias, or the like) of the IC.

In some embodiments, the design layout data of the IC may include an image (e.g., the rendered image) rendered based on GDS clip data of the IC. GDS clip data of an IC, as used herein, may refer to design layout data of the IC that is to be fabricated in a die, which is of the GDS format. In some embodiments, the design layout data of the IC may include only a design layout file (e.g., the GDS clip data) of the IC. In some embodiments, the design layout data of the IC may include only the rendered image of the IC. In some embodiments, the design layout data of the IC may include only a golden image of the IC. In some embodiments, the design layout data may include any combination of the design layout file, the golden image, and the rendered image of the IC.

Consistent with some embodiments of this disclosure, the computer-implemented method of training a machine learning model for defect detection may also include training a machine learning model using the obtained training data. In some embodiments, the machine learning model may include an autoencoder. An autoencoder in this disclosure may refer to a type of a neural network model (or simply a “neural network”).

A neural network, as used herein, may refer to a computing model for analyzing underlying relationships in a set of input data by way of mimicking human brains. Similar to a biological neural network, the neural network may include a set of connected units or nodes (referred to as “neurons”), structured as different layers, where each connection (also referred to as an “edge”) may obtain and send a signal between neurons of neighboring layers in a way similar to a synapse in a biological brain. The signal may be any type of data (e.g., a real number). Each neuron may obtain one or more signals as an input and output another signal by applying a non-linear function to the inputted signals. Neurons and edges may typically be weighted by corresponding weights to represent the knowledge the neural network has acquired. During a training process (similar to a learning process of a biological brain), the weights may be adjusted (e.g., by increasing or decreasing their values) to change the strengths of the signals between the neurons to improve the performance accuracy of the neural network. Neurons may apply a thresholding function (referred to as an “activation function”) to its output values of the non-linear function such that a signal is outputted only when an aggregated value (e.g., a weighted sum) of the output values of the non-linear function exceeds a threshold determined by the thresholding function. Different layers of neurons may transform their input signals in different manners (e.g., by applying different non-linear functions or activation functions). The output of the last layer (referred to as an “output layer”) may output the analysis result of the neural network, such as, for example, a categorization of the set of input data (e.g., as in image recognition cases), a numerical result, or any type of output data for obtaining an analytical result from the input data.

Training of the neural network, as used herein, may refer to a process of improving the accuracy of the output of the neural network. Typically, the training may be categorized into three types: supervised training, unsupervised training, and reinforcement training. In the supervised training, a set of target output data (also referred to as “labels” or “ground truth”) may be generated based on a set of input data using a method other than the neural network. The neural network may then be fed with the set of input data to generate a set of output data that is typically different from the target output data. Based on the difference between the output data and the target output data, the weights of the neural network may be adjusted in accordance with a rule. If such adjustments are successful, the neural network may generate another set of output data more similar to the target output data in a next iteration using the same input data. If such adjustments are not successful, the weights of the neural network may be adjusted again. After a sufficient number of iterations, the training process may be terminated in accordance with one or more predetermined criteria (e.g., the difference between the final output data and the target output data is below a predetermined threshold, or the number of iterations reaches a predetermined threshold). The trained neural network may be applied to analyze other input data.

In the unsupervised training, the neural network is trained without any external gauge (e.g., labels) to identify patterns in the input data rather than generating labels for them. Typically, the neural network may analyze shared attributes (e.g., similarities and differences) and relationships among the elements of the input data in accordance with one or more predetermined rules or algorithms (e.g., principal component analysis, clustering, anomaly detection, or latent variable identification). The trained neural network may extrapolate the identified relationships to other input data.

In the reinforcement learning, the neural network is trained without any external gauge (e.g., labels) in a trial-and-error manner to maximize benefits in decision making. The input data sets of the neural network may be different in the reinforcement training. For example, a reward value or a penalty value may be determined for the output of the neural network in accordance with one or more rules during training, and the weights of the neural network may be adjusted to maximize the reward values (or to minimize the penalty values). The trained neural network may apply its learned decision-making knowledge to other input data.

During the training of a neural network, a loss function (or referred to as a “cost function”) may be used to evaluate the output data. The loss function, as used herein, may map output data of a machine learning model (e.g., the neural network) onto a real number (referred to as a “loss” or a “cost”) that intuitively represents a loss or an error (e.g., representing a difference between the output data and target output data) associated with the output data. The training of the neural network may seek to maximize or minimize the loss function (e.g., by pushing the loss towards a local maximum or a local minimum in a loss curve). For example, one or more parameters of the neural network may be adjusted or updated purporting to maximize or minimize the loss function. After adjusting or updating the one or more parameters, the neural network may obtain new input data in a next iteration of its training. When the loss function is maximized or minimized, the training of the neural network may be terminated.

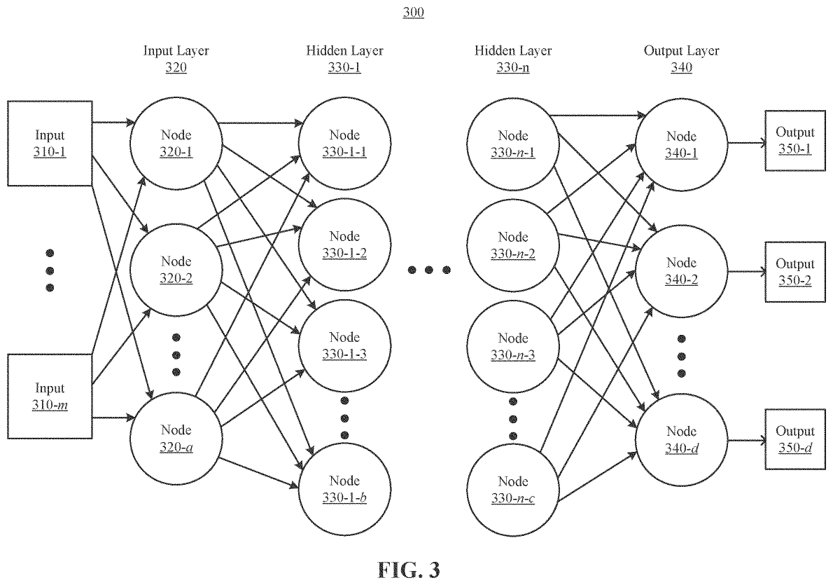

By way of example, FIG. 3 is a schematic diagram illustrating an example neural network 300, consistent with some embodiments of the present disclosure. As depicted in FIG. 3, neural network 300 may include an input layer 320 that receives inputs, including input 310-1, . . . , input 310-m (m being an integer). For example, an input of neural network 300 may include any structure or unstructured data (e.g., an image). In some embodiments, neural network 300 may obtain a plurality of inputs simultaneously. For example, in FIG. 3, neural network 300 may obtain m inputs simultaneously. In some embodiments, input layer 320 may obtain m inputs in succession such that input layer 320 receives input 310-1 in a first cycle (e.g., in a first inference) and pushes data from input 310-1 to a hidden layer (e.g., hidden layer 330-1), then receives a second input in a second cycle (e.g., in a second inference) and pushes data from input the second input to the hidden layer, and so on. Input layer 320 may obtain any number of inputs in the simultaneous manner, the successive manner, or any manner of grouping the inputs.

Input layer 320 may include one or more nodes, including node 320-1, node 320-2, . . . , node 320-a (a being an integer). A node (also referred to as a “machine perception” or a “neuron”) may model the functioning of a biological neuron. Each node may apply an activation function to received inputs (e.g., one or more of input 310-1, . . . , input 310-m). An activation function may include a Heaviside step function, a Gaussian function, a multiquadratic function, an inverse multiquadratic function, a sigmoidal function, a rectified linear unit (ReLU) function (e.g., a ReLU6 function or a Leaky ReLU function), a hyperbolic tangent (“tanh”) function, or any non-linear function. The output of the activation function may be weighted by a weight associated with the node. A weight may include a positive value between 0 and 1, or any numerical value that may scale outputs of some nodes in a layer more or less than outputs of other nodes in the same layer.

As further depicted in FIG. 3, neural network 300 includes multiple hidden layers, including hidden layer 330-1, . . . , hidden layer 330-n (n being an integer). When neural network 300 includes more than one hidden layer, it may be referred to as a “deep neural network” (DNN). Each hidden layer may include one or more nodes. For example, in FIG. 3, hidden layer 330-1 includes node 330-1-1, node 330-1-2, node 330-1-3, . . . , node 330-1-b (b being an integer), and hidden layer 330-n includes node 330-n-1, node 330-n-2, node 330-n-3, . . . , node 330-n-c (c being an integer). Similar to nodes of input layer 320, nodes of the hidden layers may apply the same or different activation functions to outputs from connected nodes of a previous layer, and weight the outputs from the activation functions by weights associated with the nodes.

As further depicted in FIG. 3, neural network 300 may include an output layer 340 that finalizes outputs, including output 350-1, output 350-2, . . . , output 350-d (d being an integer). Output layer 340 may include one or more nodes, including node 340-1, node 340-2, . . . , node 340-d. Similar to nodes of input layer 320 and of the hidden layers, nodes of output layer 340 may apply activation functions to outputs from connected nodes of a previous layer and weight the outputs from the activation functions by weights associated with the nodes.

Although nodes of each hidden layer of neural network 300 are depicted in FIG. 3 to be connected to each node of its previous layer and next layer (referred to as “fully connected”), the layers of neural network 300 may use any connection scheme. For example, one or more layers (e.g., input layer 320, hidden layer 330-1, . . . , hidden layer 330-n, or output layer 340) of neural network 300 may be connected using a convolutional scheme, a sparsely connected scheme, or any connection scheme that uses fewer connections between one layer and a previous layer than the fully connected scheme as depicted in FIG. 3.

Moreover, although the inputs and outputs of the layers of neural network 300 are depicted as propagating in a forward direction (e.g., being fed from input layer 320 to output layer 340, referred to as a “feedforward network”) in FIG. 3, neural network 300 may additionally or alternatively use backpropagation (e.g., feeding data from output layer 340 towards input layer 320) for other purposes. For example, the backpropagation may be implemented by using long short-term memory nodes (LSTM). Accordingly, although neural network 300 is depicted similar to a convolutional neural network (CNN), neural network 300 may include a recurrent neural network (RNN) or any other neural network.

An autoencoder in this disclosure may include an encoder sub-model (or simply “encoder”) and a decoder sub-model (or simply “decoder”), in which both the encoder and the decoder are symmetric neural networks. The encoder of the autoencoder may obtain input data and output a compressed representation (also referred to as a “code” herein) of the input data. The code of the input data may include extracted features of the input data. For example, the code may include a feature vector, a feature map, a feature matrix, a pixelated feature image, or any form of data representing the extracted features of the input data. During training, the decoder of the autoencoder may obtain the code outputted by the encoder and output decoded data. The goal of training the autoencoder may be to minimize the difference between the input data and the decoded data. After the training is completed, in an application of the trained autoencoder (referred to as an “inference stage”), input data may be fed to the encoder to generate a code, and the decoder of the autoencoder is not used. The code may be used as purposed output data or as feature-extracted data for other applications (e.g., for training a different machine learning model).

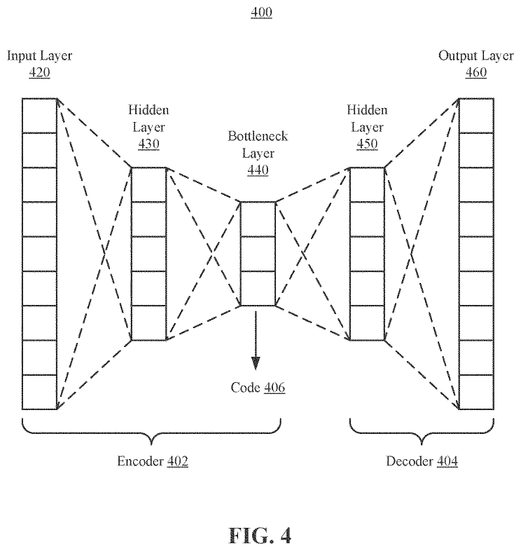

By way of example, FIG. 4 is a schematic diagram illustrating an example autoencoder 400, consistent with some embodiments of the present disclosure. As depicted in FIG. 4, autoencoder 400 includes an encoder 402 and a decoder 404. Both encoder 402 and decoder 404 are neural networks (e.g., similar to neural network 300 in FIG. 3). Encoder 402 includes an input layer 420 (e.g., similar to input layer 320 in FIG. 3), a hidden layer 430 (e.g., similar to hidden layer 330-1 in FIG. 3), and a bottleneck layer 440. Bottleneck layer 440 may function as an output layer (e.g., similar to output layer 340 in FIG. 3) of encoder 402. It should be noted that encoder 402 may include one or more hidden layers (besides hidden layer 430) and is not limited to the example embodiments as illustrated and described in association with FIG. 4. Decoder 404 includes a hidden layer 450 (e.g., similar to hidden layer 330-1 in FIG. 3) and an output layer 460 (e.g., similar to output layer 340 in FIG. 3). Bottleneck layer 440 may function as an input layer (e.g., similar to input layer 320 in FIG. 3) of decoder 404. It should be noted that decoder 404 may include one or more hidden layers (besides hidden layer 450) and is not limited to the example embodiments as illustrated and described in association with FIG. 4. The dash lines between layers of autoencoder 440 in FIG. 4 represents example connections between neurons of adjacent layers.

As depicted in FIG. 4, the structure of encoder 402 and the structure of decoder 404 are symmetric (e.g., being similar in a reverse order). For example, hidden layer 430 may include the same number (e.g., 4) of neurons as hidden layer 450, and input layer 420 may include the same number (e.g., 9) of neurons as output layer 460. Also, the connections between neurons of input layer 420 and neurons of hidden layer 430 may be symmetric with the connections between neurons of hidden layer 450 and neurons of output layer 460, and the connections between the neurons of hidden layer 430 and neurons of bottleneck layer 440 may be symmetric with the connections between the neurons of bottleneck layer 440 and the neurons of hidden layer 450.

As depicted in FIG. 4, encoder 402 may receive input data (not shown in FIG. 4) at input layer 420 and output a compressed representation of the input data at bottleneck layer 440. The compressed representation is referred to as code 406 in FIG. 4. For example, code 406 may include a feature vector, a feature map, a feature matrix, a pixelated feature image, or any form of data representing the extracted features of the input data. Decoder 404 may receive code 406 at hidden layer 450 and output decoded data (not shown in FIG. 4) at output layer 460. During the training of autoencoder 400, a difference between the decoded data and the input data may be minimized. After completing the training of autoencoder 400, encoder 402 may be used in a reference stage. Non-training data may be input to encoder 402 to generate code 406 that is a compressed representation of the non-training data. Code 406 outputted by encoder 402 in a reference stage may be used as purposed output data or as feature-extracted data for other applications (e.g., for training a different machine learning model).

In some embodiments, the machine learning model being trained using the obtained training data may include a first autoencoder and a second autoencoder. For example, the machine learning model may be a cross autoencoder. A cross autoencoder (or “XAE”), as used herein, refers to a machine learning model that includes a first autoencoder and a second autoencoder, in which the first autoencoder includes a first encoder and a first decoder, the second autoencoder includes a second encoder and a second decoder, the second decoder is configured to obtain a first code outputted by the first encoder, and the first decoder is configured to obtain a second code outputted by the second encoder.

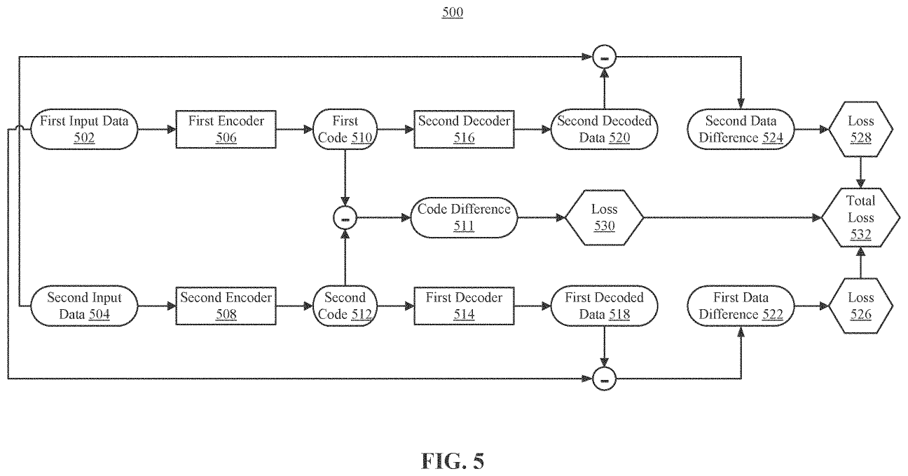

By way of example, FIG. 5 is a schematic diagram illustrating an example cross autoencoder 500, consistent with some embodiments of the present disclosure. Cross autoencoder 500 includes a first autoencoder (not labeled in FIG. 5) and a second autoencoder (not labeled in FIG. 5). The first autoencoder includes a first encoder 506 (e.g., similar to encoder 402 of FIG. 4) and a first decoder 514 (e.g., similar to decoder 404 of FIG. 4). The second autoencoder includes a second encoder 508 (e.g., similar to encoder 402 of FIG. 4) and a second decoder 516 (e.g., similar to decoder 404 of FIG. 4). In some embodiments, the first autoencoder may have the same structure as the second autoencoder, such as, for example, the same number of layers, the same number of neurons for each layer, the same inter-layer connections between corresponding layers, or the like.

As depicted in FIG. 5, first encoder 506 (of the first autoencoder) may obtain first input data 502 and output a first code 510. Second encoder 508 (of the second autoencoder) may obtain second input data 504 and output a second code 512. First input data 502 may be different from second input data 504. First decoder 514 (of the first autoencoder) may obtain second code 512 and output first decoded data 518. Second decoder 516 (of the second autoencoder) may obtain first code 510 and output second decoded data 520. First input data 502 and first decoded data 518 may be of the same datatype (e.g., both being of an image type), and second input data 504 and second decoded data 520 may be of the same datatype (e.g., both being of a text type).

As depicted in FIG. 5, a difference between first code 510 and second code 512 may be determined as a code difference 511. For example, if first code 510 and second code 512 are feature vectors, code difference 511 may be a vector determined by subtracting first code 510 from second code 512 or by subtracting second code 512 from first code 510.

Consistent with some embodiments of this disclosure, the computer-implemented method of training a machine learning model for defect detection may further include inputting the inspection image to the first encoder to output the first code, in which the first code may represent a first pixelated image. The method may further include inputting the design layout data to the second encoder to output the second code, in which the second code may represent a second pixelated image. The method may further include determining a pixelated difference image, in which each pixel of the pixelated difference image may represent a difference between a first value associated with a first pixel in the first pixelated image and a second value associated with a second pixel in the second pixelated image.

By way of example, with reference to FIG. 5, assuming first input data 502 is the inspection image and second input data 504 is the rendered image, the inspection image may be inputted to first encoder 506 to output first code 510 that may represent the first pixelated image. The rendered image may be inputted to second encoder 508 to output second code 512 that may represent the second pixelated image. The first pixelated image may have a reduced dimension (e.g., reduced size, reduced color depth, reduced color spectrum range, or the like) compared with the inspection image. The second pixelated image may also have a reduced dimension compared with the rendered image. The first pixelated image may have the same size (e.g., the same height and width) as the second pixelated image. In such an example, code difference 511 may be the pixelated difference image. The pixelated difference image may have the same size (e.g., the same height and width) as the first pixelated image and the second pixelated image. Each pixel of code difference 511 may have a value (e.g., a difference value, an absolute value of the difference value, a square of the absolute value, or the like) representing a difference between a first value (e.g., a grayscale-level value, an RGB value, or the like) associated with a first pixel in the first pixelated image and a second value (e.g., a grayscale-level value, an RGB value, or the like) associated with a second pixel in the second pixelated image. The first pixel and the second pixel may be co-located.

Being co-located, as described herein, may refer to two objects having the same relative position in a coordinate system with the same definition of origin. For example, the first pixel in the first feature image may be positioned at a first coordinate (x₁, y₁) with respect to a first origin (0, 0) in the first image (e.g., the first origin being a top-left corner, a top-right corner, a bottom-left corner, a bottom-right corner, a center, or any position of the first image). The second pixel in the second feature image may be positioned at a second coordinate (x₂, y₂) with respect to a second origin (0, 0) in the second image, in which the second origin shares the same definition as the first origin. For example, the second origin may be a top-left corner of the second image if the first origin is a top-left corner of the first image, a top-right corner of the second image if the first origin is a top-right corner of the first image, a bottom-left corner of the second image if the first origin is a bottom-left corner of the first image, a bottom-right corner of the second image if the first origin is a bottom-right corner of the first image, or a center of the second image if the first origin is a center of the first image. In such cases, if x₁ and x₂ have the same value, and y₁ and y₂ have the same value, the first pixel in the first feature image and the second pixel in the second feature image may be referred to as “co-located.”

Consistent with some embodiments of this disclosure, the computer-implemented method of training a machine learning model for defect detection may further include inputting the first code to the second decoder to output the decoded inspection image. The method may also include inputting the second code to the first decoder to output the decoded design layout data.

By way of example, with reference to FIG. 5, assuming first input data 502 is the inspection image and second input data 504 is the rendered image, first code 510 may be inputted to second decoder 516 to output the decoded inspection image as second decoded data 520. Second code 512 may be inputted to first decoder 514 to output the decoded design layout data (e.g., the decoded rendered image) as first decoded data 518.

In some embodiments, a loss function for training the machine learning model (e.g., cross autoencoder 500) may include a first component representing a difference between a first code outputted by the first encoder and a second code outputted by the second encoder. By way of example, with reference to FIG. 5, code difference 511 may represent a difference between first code 510 and second code 512. A loss 530 may be generated based on code difference 511. Loss 530 may be the first component of the loss function (e.g., a total loss 532) of the machine learning model.

In some embodiments, the first component of the loss function may be generated based on the difference between the first code and the second code. By way of example, with reference to FIG. 5, assuming first code 510 represents a first pixelated image having 2×2 pixels, and assuming second code 512 represents a second pixelated image having 2×2 pixels. The coordinates of the 2×2 pixels may be represented as (0, 0), (0, 1), (1, 0), and (1, 1), respectively. Code difference 511 may also represent a difference image having 2×2 pixels. A pixel of code difference 511 located at (x, y) ({x, y}={0, 1}) may have a mean square error (MSE) value determined between a value of a pixel of first code 510 located at (x, y) and a value of a pixel of second code 512 located at (x, y). Pixels of code difference 511 may be represented by Eq. (1):

$${P}_{( x , y )}^{CD} = \frac{1}{2} {( {P}_{( x , y )}^{A} - {P}_{( x , y )}^{B} )}^{2} , \{ x , y \} = \{ 0 , 1 \} \qquad Eq . ( 1 )$$

In Eq. (1), P_{(x,y)}^{CD} represents a value associated with a pixel located at coordinate (x, y) in code difference 511. P_{(x,y)}^{A} represents a value (e.g., a grayscale-level value, an RGB value, or the like) associated with a pixel located at coordinate (x, y) in first code 510. P_{(x,y)}^{B} represents a value (e.g., a grayscale-level value, an RGB value, or the like) associated with a pixel located at coordinate (x, y) in second code 512. P_{(x,y)}^{A} and P_{(x,y)}^{B} may be of the same type of values. As shown in Eq. (1), P_{(x,y)}^{CD} is an MSE determined based on P_{(x,y)}^{A} and P_{(x,y)}^{B}.

With reference to FIG. 5 and Eq. (1), by way of example, loss 530 may be determined as a sum of the values associated with all pixels of code difference 511. For example, loss 530 may be represented as [symbol] in Eq. (2):

$${ℒ}_{1} = {\sum }_{\{ x , y \} = \{ 0 , 1 \}} {P}_{( x , y )}^{CD} \qquad Eq . ( 2 )$$

In some embodiments, besides the first component (e.g., loss 530), the loss function for training the machine learning model (e.g., cross autoencoder 500) may further include a second component representing a difference between the inspection image and a decoded inspection image outputted by the first decoder, and a third component representing a difference between the design layout data and decoded design layout data outputted by the second decoder.

By way of example, with reference to FIG. 5, assuming first input data 502 is the inspection image and second input data 504 is the rendered image, first decoded data 518 may be the decoded inspection image outputted by first decoder 514 and having the same size (e.g., the same height and width) as the inspection image. Second decoded data 520 may be the decoded design layout data (e.g., the decoded rendered image) outputted by second decoder 516 and have the same size (e.g., the same height and width) as the rendered image. A difference between first input data 502 and first decoded data 518 may be determined as first data difference 522, and a difference between second input data 504 and second decoded data 520 may be determined as second data difference 524.

In such an example, first data difference 522 may be a pixelated image having the same size as the inspection image or the decoded inspection image. Each pixel of first data difference 522 may have a value (e.g., a difference value, an absolute value of the difference value, a square of the absolute value, or the like) representing a difference between a first value (e.g., a grayscale-level value, an RGB value, or the like) associated with a first pixel in the inspection image and a second value (e.g., a grayscale-level value, an RGB value, or the like) associated with a second pixel in the decoded inspection image, in which the first pixel and the second pixel are co-located. Similarly, second data difference 524 may be a pixelated image having the same size as the rendered image or the decoded rendered image. Each pixel of second data difference 524 may have a value (e.g., a difference value, an absolute value of the difference value, a square of the absolute value, or the like) representing a difference between a third value (e.g., a grayscale-level value, an RGB value, or the like) associated with a third pixel in the rendered image and a fourth value (e.g., a grayscale-level value, an RGB value, or the like) associated with a fourth pixel in the decoded rendered image, in which the third pixel and the fourth pixel are co-located.

In some embodiments, the second component of the loss function may be generated based on the difference between the inspection image and the decoded inspection image, and the third component of the loss function may be generated based on the difference between the rendered image and the decoded rendered image. By way of example, with reference to FIG. 5, the second component may be loss 526, and the third component may be loss 528. Assuming first data difference 522 represents a difference image having 4×4 pixels, and assuming second data difference 524 represents a difference image having 4×4 pixels. A pixel of first data difference 522 located at (m, n) ({m, n}={0, 1, 2, 3}) may have a mean square error (MSE) value determined between a value of a pixel of the inspection image located at (m, n) and a value of a pixel of the decoded inspection image located at (m, n). A pixel of second data difference 524 located at (p, q) ({p, q}={0, 1, 2, 3}) may have a mean square error (MSE) value determined between a value of a pixel of the rendered image located at (p, q) and a value of a pixel of the decoded rendered image located at (p, q). Pixels of first data difference 522 and pixels of second data difference 524 may be represented by Eq. (3) and Eq. (4), respectively:

$${P}_{( m , n )}^{D 1} = \frac{1}{2} {( {P}_{( m , n )}^{I} - {P}_{( m , n )}^{{I}^{′}} )}^{2} , \{ m , n \} = \{ 0 , 1 , 2 , 3 \} \qquad Eq . ( 3 )$$

$${P}_{( p , q )}^{D 2} = \frac{1}{2} {( {P}_{( p , q )}^{R} - {P}_{( p , q )}^{{R}^{′}} )}^{2} , \{ p , q \} = \{ 0 , 1 , 2 , 3 \} \qquad Eq . ( 4 )$$

In Eq. (3), P_{(m,n)}^{D1} represents a value associated with a pixel located at coordinate (m, n) in first data difference 522. P_{(m,n)}^{I} represents a value (e.g., a grayscale-level value, an RGB value, or the like) associated with a pixel located at coordinate (m, n) in the inspection image (e.g., represented by first input data 502). P_{(m,n)}^{I′} represents a value (e.g., a grayscale-level value, an RGB value, or the like) associated with a pixel located at coordinate (m, n) in the decoded inspection image (e.g., represented by first decoded data 518). P_{(m,n)}^{I} and P_{(m,n)}^{I′} may be of the same type of values. As shown in Eq. (3), P_{(m,n)}^{D1} is an MSE determined based on P_{(m,n)}^{I} and P_{(m,n)}^{I′}.

In Eq. (4), P_{(m,n)}^{D2} represents a value associated with a pixel located at coordinate (p, q) in second data difference 524. P_{(m,n)}^{R} represents a value (e.g., a grayscale-level value, an RGB value, or the like) associated with a pixel located at coordinate (p, q) in the rendered image (e.g., represented by second input data 504). P_{(m,n)}^{R′} represents a value (e.g., a grayscale-level value, an RGB value, or the like) associated with a pixel located at coordinate (p, q) in the decoded rendered image (e.g., represented by second decoded data 520). P_{(m,n)}^{R} and P_{(m,n)}^{R′} may be of the same type of values. As shown in Eq. (4), P_{(m,n)}^{D2} is an MSE determined based on P_{(m,n)}^{R} and P_{(m,n)}^{R′}.

In some embodiments, the loss function for training the machine learning model (e.g., cross autoencoder 500) may be a sum of the first component, the second component, and the third component. By way of example, with reference to FIG. 5, the first component, the second component, and the third component may be loss 530, loss 526, and loss 528, respectively. The loss function may be total loss 532, which can be a sum of loss 530, loss 526, and loss 528.

With reference to FIG. 5 and Eqs. (3)-(4), by way of example, loss 526 may be determined as a sum of the values associated with all pixels of first data difference 522, and loss 528 may be determined as a sum of the values associated with all pixels of second data difference 524. For example, loss 526 and loss 528 may be represented as [symbol] in Eq. (5) and [symbol] in Eq. (6), respectively:

$${ℒ}_{2} = {\sum }_{\{ m , n \} = \{ 0 , 1 , 2 , 3 \}} {P}_{( m , n )}^{D 1} \qquad Eq . ( 5 )$$

$${ℒ}_{3} = {\sum }_{\{ p , q \} = \{ 0 , 1 , 2 , 3 \}} {P}_{( p , q )}^{D 2} \qquad Eq . ( 6 )$$

With reference to Eqs. (2), (5), and (6), by way of example, total loss 532 may be represented as [symbol] in Eq. (7):

$$ℒ = {ℒ}_{1} + {ℒ}_{2} + {ℒ}_{3} \qquad Eq . ( 7 )$$

By way of example, with reference to FIG. 5 and Eqs. (1)-(7), the training of cross autoencoder 500 may aim to minimize total loss 532 (e.g., [symbol] in Eq. (7)). For example, first input data 502 may include N (N being an integer) entries, and second input data 504 may also include N entries. Each entry of first input data 502 may be paired with one entry of second input data 504, forming N pairs of corresponding data entries. In a current training iteration, the first autoencoder of cross autoencoder 500 may receive first input data 502 (e.g., by first encoder 506) and output first decoded data 518 (e.g., by first decoder 514), and the second autoencoder of cross autoencoder 500 may receive second input data 504 (e.g., by second encoder 508) and output second decoded data 520 (e.g., by second decoder 516). Code difference 511, first data difference 522, and second data difference 524 may be determined as described in association with FIG. 5 and Eqs. (1)-(6). Values of loss 530, loss 526, and loss 528 may also be determined as described in association with Eqs. (1)-(6). The value of total loss 532 may then be determined as described in association with Eq. (7). If the value of total loss 532 in the current training iteration is not greater than the value of total loss 532 in a previous training iteration by a predetermined threshold, one or more parameter values of at least one of first encoder 506, second encoder 508, first decoder 514, or second decoder 520 may be updated such that the value of total loss 532 in a next training iteration is expected to be smaller than or equal to the value of total loss 532 in the current training iteration. If the value of total loss 532 in the current training iteration is greater than the value of total loss 532 in a previous training iteration by the predetermined threshold, the training of cross autoencoder 500 may be deemed as completed.

Consistent with some embodiments of this disclosure, the first component of the loss function may further include a parameter. In response to the parameter being of a first value (e.g., a negative value), the machine learning model may be trained using a supervised learning technique. In response to the parameter being of a second value (e.g., a non-negative value) different from the first value, the machine learning model may be trained using an unsupervised learning technique.

By way of example, the first component may be loss 530 of FIG. 5, and the parameter may be associated with each pixel of code difference 511. In such an example, loss 530 may be represented by [symbol] in Eq. (8):

$${ℒ}_{1} = {\sum }_{\{ x , y \} = \{ 0 , 1 \}} {P}_{( x , y )}^{CD} \cdot {W}_{( x , y )} \qquad Eq . ( 8 )$$

In Eq. (8), W_{(x,y)} represents a parameter value associated with a pixel located at coordinate (x, y) in code difference 511. In some embodiments, with reference to Eqs. (1) and (8), assuming first input data 502 represents the inspection image and second input data 504 represents the rendered image, if a pixel of first code 510 located at (x, y) ({x, y}={0, 1}) is linked to a known defect pattern in the inspection image, W_{(x,y)} may be set to be a negative value (e.g., -1). If a pixel of first code 510 located at (x, y) ({x, y}={0, 1}) is linked to none of known defect patterns in the inspection image, W_{(x,y)} may be set to be a positive value (e.g., +1). When W_{(x,y)} has a negative value, the training of cross autoencoder 500 may be conducted using a supervised learning technique, in which a pixel of second code 512 located at (x, y) ({x, y}={0, 1}) may be used as reference, and in Eq. (8) may be used to [symbol] maximize code difference 511. When W_{(x,y)} has a positive value, the training of cross autoencoder 500 may be conducted using an unsupervised learning technique, in which [symbol] in Eq. (8) may be used to minimize code difference 511.

It should be noted that the manners of assigning values to W_{(x,y)} may be various and are not limited to the examples described herein. For example, if a pixel of first code 510 located at (x, y) ({x, y}={0, 1}) is linked to a known defect pattern in the inspection image, W_{(x,y)} may be set to be a positive value (e.g., +3). If a pixel of first code 510 located at (x, y) ({x, y}={0, 1}) is linked to none of known defect patterns in the inspection image, W_{(x,y)} may be set to be a negative value (e.g., -2).

By use of the parameter to control the training mode (e.g., supervised learning or unsupervised learning), the training of the machine learning model may be more flexible. For example, when the machine learning model is trained using the supervised learning technique, the resulting trained machine learning model can be effectively more sensitive to identify known defect patters or defects of interest.

Consistent with some embodiments of this disclosure, when the design layout data of the IC includes the rendered image rendered based on the GDS clip data of the IC, the computer-implemented method of training a machine learning model for defect detection may further include aligning the inspection image and the rendered image. By way of example, corresponding pixel locations may be identified in both the inspection image and the rendered image, and the corresponding pixel locations of the inspection image and the rendered image may be adjusted to have the same coordinates in a common coordinate system by moving (e.g., translating or rotating) at least one of the inspection image or the rendered image in the common coordinate system.

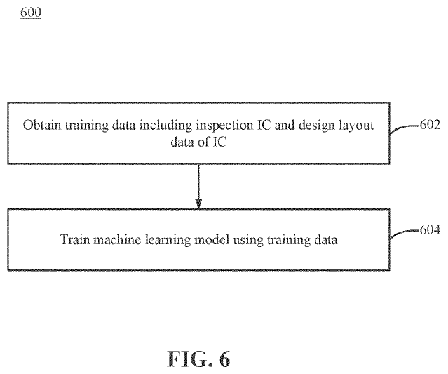

By way of example, FIG. 6 is a flowchart illustrating an example method 600 for training a machine learning model for defect detection, consistent with some embodiments of the present disclosure. Method 600 may be performed by a controller that may be coupled with a charged-particle beam tool (e.g., charged-particle beam inspection system 100) or an optical beam tool. For example, the controller may be controller 109 in FIG. 2. The controller may be programmed to implement method 600.

At step 602, the controller may obtain training data including an inspection image of a fabricated integrated circuit (IC) and design layout data of the IC. In some embodiments, the design layout data may include a golden image or an image rendered based on graphic design system (GDS) clip data of the IC. For example, the inspection image may be represented by first input data 502 in FIG. 5, and the rendered image may be represented by second input data 504 in FIG. 5. In some embodiments, after step 602, the controller may further align the inspection image and the rendered image.

At step 604, the controller may train a machine learning model (e.g., cross autoencoder 500 of FIG. 5) using the training data. The machine learning model may include a first autoencoder and a second autoencoder. The first autoencoder may include a first encoder (e.g., first encoder 506 of FIG. 5) and a first decoder (e.g., first decoder 514 of FIG. 5). The second autoencoder may include a second encoder (e.g., second encoder 508 of FIG. 5) and a second decoder (e.g., second decoder 516 of FIG. 5). The first decoder may obtain a second code (e.g., second code 512 of FIG. 5) outputted by the second encoder. The second decoder may obtain a first code (e.g., first code 510 of FIG. 5) outputted by the first encoder.

In some embodiments, to train the machine learning model at step 604, the controller may input the inspection image to the first encoder to output the first code that represents a first pixelated image. The controller may also input the design layout data to the second encoder to output the second code that represents a second pixelated image. The controller may then determine a pixelated difference image (e.g., code difference 511 of FIG. 5). Each pixel of the pixelated difference image may represent a difference between a first value associated with a first pixel in the first pixelated image and a second value associated with a second pixel in the second pixelated image. The first pixel and the second pixel may be co-located.

In some embodiments, a loss function (e.g., total loss 532 in FIG. 5) for training the machine learning model may include a first component (e.g., loss 530 or [symbol] in Eq. (2)) representing a difference between the first code outputted by the first encoder and the second code outputted by the second encoder. In some embodiments, the loss function may further include a second component (e.g., loss 526 or [symbol] in Eq. (5)) representing a difference between the inspection image and a decoded inspection image outputted by the first decoder, and a third component (e.g., loss 582 or [symbol] in Eq. (6)) representing a difference between the design layout data and decoded design layout data outputted by the second decoder. In some embodiments, the loss function (e.g., [symbol] in Eq. (7)) may be a sum of the first component, the second component, and the third component.

In some embodiments, to train the machine learning model at step 604, the controller may input the first code to the second decoder to output the decoded design layout data. The controller may also input the second code to the first decoder to output the decoded inspection image.

In some embodiments, the first component (e.g., loss 530 or [symbol] in Eq. (2)) may further include a parameter (e.g., W_{(x,y)} in Eq. (8)). To train the machine learning model at step 604, the controller may train the machine learning model using a supervised learning technique in response to the parameter being of a first value (e.g., +1). The controller may also train the machine learning model using an unsupervised learning technique in response to the parameter being of a second value (e.g., -1) different from the first value.

The technical solutions of this disclosure also provides a method for training multiple machine learning models separately. The separately trained machine learning model may be combined to use for defect detection. Each of the multiple machine learning models may apply different data augmentation strategies for training. For example, a first machine learning model may be trained using regular inspection images and their corresponding design layout data. For tackling nuisance caused by random shifts of polygons between inspection images and their corresponding design layout data, a second machine learning model may be trained using the regular inspection images and adjusted design layout data that applies random shifts to one or more of its polygons. The trained second machine learning model may have higher sensitivity in detecting defects caused by random shifts. For tackling nuisance caused by random scaling of polygons between inspection images and their corresponding design layout data, a third machine learning model may be trained using the regular inspection images and adjusted design layout data that applies random resizing to one or more of its polygons. The trained third machine learning model may have higher sensitivity in detecting defects caused by random scaling. The trained first, second, and third machine learning models may be combined to use in a reference stage for more accurate and more efficient defect detection.

Consistent with some embodiments of this disclosure, this disclosure provides a computer-implemented method of training a plurality of machine learning models for defect detection. The method may include obtaining first data including a first inspection image of a fabricated first integrated circuit (IC) and first design layout data of the first IC. The method may also include training a first machine learning model using the first data. The method may further include obtaining second data including a second inspection image of a fabricated second IC and second design layout data of the second IC. The method may further include generating adjusted design layout data by adjusting a polygon of the second design layout data. The method may further include training a second machine learning model using the second inspection image and adjusted design layout data. In some embodiments, the first machine learning model may include a first cross autoencoder (e.g., structurally similar to cross autoencoder 500 of FIG. 5), and the second machine learning model may include a second cross autoencoder (e.g., structurally similar to cross autoencoder 500 of FIG. 5) different from the first cross autoencoder.

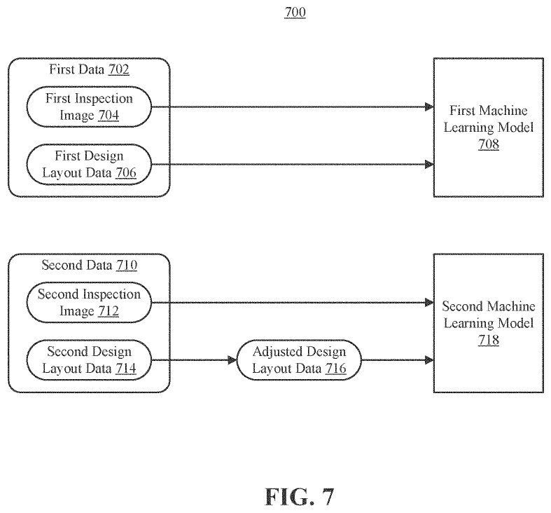

By way of example, FIG. 7 is a schematic diagram illustrating two example machine learning models for training, consistent with some embodiments of the present disclosure. As depicted in FIG. 7, first data 702 includes a first inspection image 704 of a fabricated first IC and first design layout data 706 of the first IC. The first data 702 may be used to train a first machine learning model 708. For example, first machine learning model may be a cross autoencoder similar to cross autoencoder 500 of FIG. 5, in which first inspection image 704 may be similar to first input data 502, and first design layout data 706 may be similar to second input data 504. As depicted in FIG. 7, second data 710 includes a second inspection image 712 of a fabricated second IC and second design layout data 714 of the second IC. A polygon of second design layout data 714 may be adjusted to generate adjusted design layout data 716. Second inspection image 712 and adjusted design layout data 716 may be used to train a second machine learning model 718.

In some embodiments, the first design layout data (e.g., first design layout data 706) may include a first image rendered based on first graphic design system (GDS) clip data of the first IC. The second design layout data (e.g., second design layout data 714) may include a second image rendered based on second GDS clip data of the second IC. In some embodiments, before training the first machine learning model and the second machine learning model, the method may further include aligning the first inspection image and the first rendered image and aligning the second inspection image and the second rendered image.

In some embodiments, to adjust the polygon of the second design layout data, the method may further include at least one of randomly moving the polygon in the second design layout data or randomly resizing the polygon in the second design layout data. For example, if the second design layout data includes a second rendered image that includes the polygon, the polygon may be moved to a random position in the second rendered image. As another example, the polygon may be resized to a random size in the second rendered image.

In some embodiments, the first IC may be the same as the second IC. The first inspection image may be the same as the second inspection image. The first design layout data may be the same as the second design layout data. By way of example, with reference to FIG. 7, first inspection image 704 and second inspection image 712 may be the same inspection image, and first design layout data 706 and second design layout data 714 may be the same design layout data.

In some embodiments, the first IC may be different from the second IC. The first inspection image may be different from the second inspection image. The first design layout data may be different from the second design layout data. By way of example, with reference to FIG. 7, first inspection image 704 and second inspection image 712 may be different inspection images (e.g., inspection images of different fabricated ICs), and first design layout data 706 and second design layout data 714 may be different design layout data (e.g., design layout data of different ICs).

In some embodiments, the first data may include a first set of inspection images of fabricated ICs and a first set of design layout data of the fabricated ICs, in which each piece of the first set of design layout data may correspond to (e.g., paired with) one of the first set of inspection images. The second data may include a second set of inspection images of fabricated ICs and a second set of design layout data of the fabricated ICs, in which each piece of the second set of design layout data may correspond to (e.g., paired with) one of the second set of inspection images. By way of example, with reference to FIG. 7, first inspection image 704 may represent the first set of inspection images, and first design layout data 706 may represent the first set of design layout data. Second inspection image 712 may represent the second set of inspection images, and second design layout data 714 may represent the second set of design layout data.

In some embodiments, when the first data includes the first set of inspection images and the first set of design layout data, and when the second data includes the second set of inspection images and the second set of design layout data, the first data may be the same as the second data. The first set of inspection images may be the same as the second set of inspection images. The first set of design layout data may be the same as the second set of design layout data. In such cases, in some embodiments, to generate the adjusted design layout data, a polygon of at least one piece of the second set of design layout data may be adjusted. The at least one piece of the second set of design layout data may include the second design layout data.

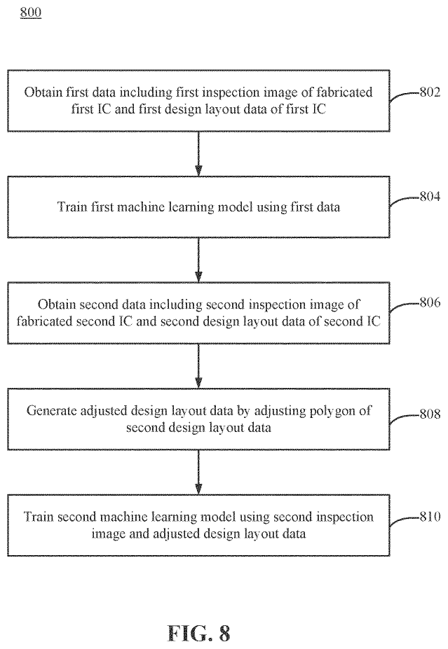

By way of example, FIG. 8 is a flowchart illustrating an example method 800 for training a plurality of machine learning models for defect detection, consistent with some embodiments of the present disclosure. Method 800 may be performed by a controller that may be coupled with a charged-particle beam tool (e.g., charged-particle beam inspection system 100) or an optical beam tool. For example, the controller may be controller 109 in FIG. 2. The controller may be programmed to implement method 800.

At step 802, the controller may obtain first data (e.g., first data 702 of FIG. 7) including a first inspection image (e.g., first inspection image 712 of FIG. 7) of a fabricated first integrated circuit (IC) and first design layout data (e.g., first design layout data 706 of FIG. 7) of the first IC. In some embodiments, the first design layout data may include a first image rendered based on first graphic design system (GDS) clip data of the first IC. In some embodiments, the first data may include a first set of inspection images of fabricated ICs and a first set of design layout data of the fabricated ICs, in which each piece of the first set of design layout data may correspond to one of the first set of inspection images.

At step 804, the controller may train a first machine learning model (e.g., first machine learning model 708 of FIG. 7) using the first data. In some embodiments, if the first design layout data includes the first rendered image, before training the first machine learning model, the controller may align the first inspection image and the first rendered image. In some embodiments, the first machine learning model may include a first cross autoencoder (e.g., structurally similar to cross autoencoder 500 of FIG. 5).

At step 806, the controller may obtain second data (e.g., second data 710 of FIG. 7) including a second inspection image (e.g., second inspection image 712 of FIG. 7) of a fabricated second IC and second design layout data of the second IC. In some embodiments, the second design layout data may include a second image rendered based on second GDS clip data of the second IC. In some embodiments, the second data may include a second set of inspection images of fabricated ICs and a second set of design layout data of the fabricated ICs, in which each piece of the second set of design layout data may correspond to one of the second set of inspection images.

In some embodiments, the first IC may be the same as the second IC. The first inspection image may be the same as the second inspection image. The first design layout data may be the same as the second design layout data.

In some embodiments, when the first data includes the first set of inspection images and the first set of design layout data, and when the second data includes the second set of inspection images and the second set of design layout data, the first data may be the same as the second data. The first set of inspection images may be the same as the second set of inspection images. The first set of design layout data may be the same as the second set of design layout data.

At step 808, the controller may generate adjusted design layout data by adjusting a polygon of the second design layout data. In some embodiments, to adjust the polygon of the second design layout data, the controller may perform at least one of randomly moving the polygon in the second design layout data, or randomly resizing the polygon in the second design layout data. In some embodiments, if the second design layout data includes the second rendered image, before generating the adjusted design layout data, the controller may align the second inspection image and the second rendered image.

In some embodiments, when the second data includes the second set of inspection images and the second set of design layout data, to generate the adjusted design layout data, the controller may adjust a polygon of at least one piece of the second set of design layout data. The at least one piece of the second set of design layout data may include the second design layout data.

At step 810, the controller may train a second machine learning model (e.g., second machine learning model 718 of FIG. 7) using the second inspection image and adjusted design layout data. In some embodiments, the second machine learning model may include a second cross autoencoder (e.g., structurally similar to cross autoencoder 500 of FIG. 5) different from the first cross autoencoder.

Consistent with some embodiments of this disclosure, this disclosure provides a computer-implemented method of defect detection using a trained machine learning model. The method may include obtaining an inspection image of a fabricated integrated circuit (IC) and design layout data of the IC. In some embodiments, the design layout data comprises an image rendered based on graphic design system (GDS) clip data of the IC.

Consistent with some embodiments of this disclosure, the method may also include inputting the inspection image and the design layout data to a trained machine learning model (e.g., including one or more cross autoencoders) to generate a defect map. The trained machine learning model may include a first cross autoencoder. The first cross autoencoder may include a first autoencoder configured to obtain the inspection image as input and a second autoencoder configured to obtain the design layout data as input.

By way of example, with reference to FIG. 5, the trained machine learning model may include cross autoencoder 500. For example, the trained machine learning model may include first encoder 506 (of the first autoencoder) and second encoder 508 (of the second autoencoder). In some embodiments, the trained machine learning model includes no decoder. First encoder 506 may be configured to receive the inspection image as input, and second encoder 508 may be configured to receive the design layout data as input.

In some embodiments, to generate the defect map, the method may include inputting the inspection image to the first autoencoder to output a first code that represents a first pixelated image. The method may also include inputting the design layout data to the second autoencoder to output a second code that represents a second pixelated image. The method may further include determining the defect map as a pixelated image, in which each pixel of the defect map may represent a difference between a first value associated with a first pixel in the first pixelated image and a second value associated with a second pixel in the second pixelated image. The first pixel and the second pixel may be co-located.

By way of example, with reference to FIG. 5, the inspection image may be inputted to the first autoencoder (e.g., first encoder 506) to output first code 510. The design layout data (e.g., the rendered image) may be inputted to the second autoencoder (e.g., second encoder 508) to output second code 512. The trained machine learning model may generate code difference 511 as a pixelated image based on first code 510 and second code 512 in a manner described in association with FIG. 5, and then determine the defect map as code difference 511.

Consistent with some embodiments of this disclosure, the method may further include detecting a potential defect in the inspection image based on the defect map. For example, the defect map may include one or more flagged locations indicative of potential defects. The flagged locations may include pixels having values exceeding a predetermined threshold (e.g., grayscale difference values exceeding a predetermined threshold). The locations in the inspection image corresponding to the flagged locations of the defect map may be inputted to a defect detection application for further defect analysis. The defect detection application may determine whether the flagged locations do include potential defects.

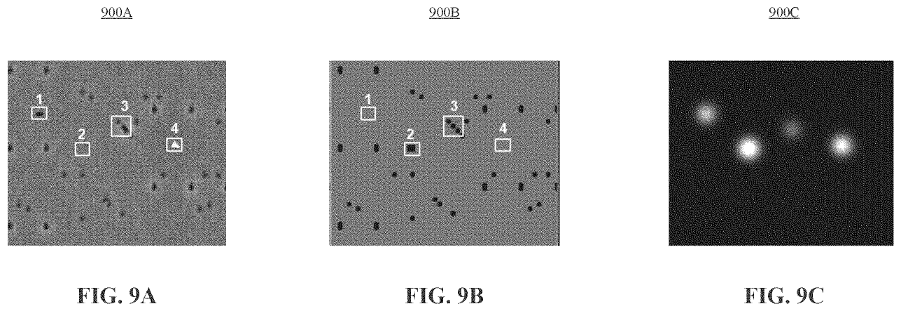

By way of example, FIG. 9A illustrates an example inspection image 900A of a fabricated integrated circuit, consistent with some embodiments of the present disclosure. FIG. 9B illustrates an example rendered image 900B of the fabricated integrated circuit, consistent with some embodiments of the present disclosure. FIG. 9C illustrates an example defect map 900C generated using the inspection image 900A and the rendered image 900B, consistent with some embodiments of the present disclosure. For example, inspection image 900A may be inputted to first encoder 506 of FIG. 5, and rendered image 900B may be inputted to second encoder 508 of FIG. 5. The trained machine learning model may then output defect map 900C as code difference 511. As depicted in FIG. 9C, defect map 900C includes four bright spots representing flagged regions of potential defects in inspection image 900A. Defect map 900C may be inputted to a defect detection application that may checked the flagged regions to identify defects.

In FIGS. 9A-9C, the four bright spots in defect map 900C correspond to four defects labeled as 1 to 4 in inspection image 900A. Defect 1 may represent a misprinted pattern that exist in inspection image 900A but does not exist in a corresponding location of rendered image 900B. Defect 2 may represent a missing pattern that exist in a corresponding location of rendered image 900B but does not exist in inspection image 900A. Defect 3 may represent a bridge defect, in which circuit components designed as separate (represented by separate black dots in region 3 of rendered image 900B) are fabricated to connect to each other (represented by connected black dots in region 3 of inspection image 900A). Defect 4 may represent an external particle (represented by a bright dot in region 4 of inspection image 900A) falling on the fabricated IC. As depicted in FIGS. 9A-9C, defect map 900C captures all four defects.

In some embodiments, the trained machine learning model may further include a second cross autoencoder different from the first cross autoencoder. The second cross autoencoder model may include a third autoencoder configured to obtain the inspection image as input and a fourth autoencoder configured to obtain the design layout data as input.

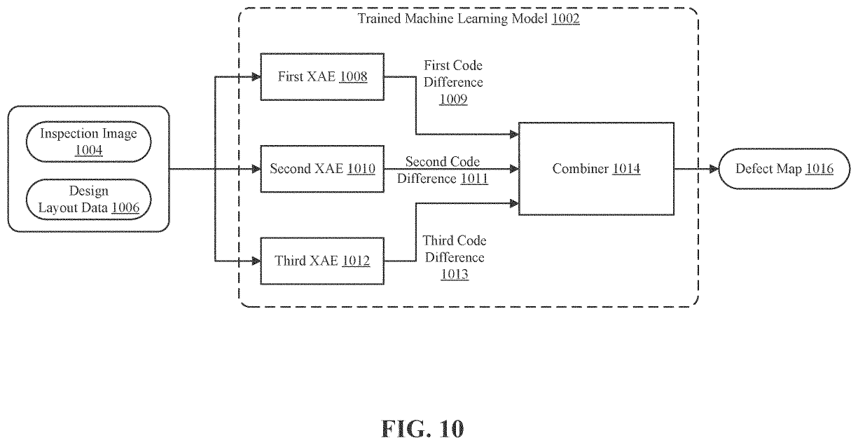

By way of example, FIG. 10 is a schematic diagram illustrating a defect detection process 1000 using a trained machine learning model 1002, consistent with some embodiments of the present disclosure. Trained machine learning model 1002 may be used in a reference stage in FIG. 10. As depicted in FIG. 10, trained machine learning model 1002 includes a combiner 1014 and three cross autoencoders: first XAE 1008, second XAE 1010, and third XAE 1012. Each of first XAE 1008, second XAE 1010, and third XAE 1012 may be structurally similar to cross autoencoder 500 of FIG. 5. By way of example, first XAE 1008 may be similar to first machine learning model 708 of FIG. 7 and may be trained using first data 702. Second XAE 1010 may be similar to second machine learning model 718 of FIG. 7 and may be trained using second inspection image 712 and adjusted design layout data 716, in which adjusted design layout data 716 is generated by randomly moving a polygon in second design layout data 714. Third XAE 1012 may be similar to second machine learning model 718 of FIG. 7 and may be trained using second inspection image 712 and adjusted design layout data 716, in which adjusted design layout data 716 is generated by randomly resizing a polygon in second design layout data 714.

As depicted in FIG. 10, each of first XAE 1008, second XAE 1010, and third XAE 1012 may receive inspection image 1004 of a fabricated IC and design layout data 1006 of the IC as input, and output first code difference 1009, second code difference 1011, and third code difference 1013, respectively. First code difference 1009, second code difference 1011, and third code difference 1013 may be similar to code difference 511 in FIG. 5, which may be pixelated images. First code difference 1009, second code difference 1011, and third code difference 1013 may be inputted to combiner 1014 to generate a defect map 1016 (e.g., similar to defect map 900C of FIG. 9C).

In some embodiments, when the trained machine learning model includes the second cross autoencoder, to generate the defect map, the method may include inputting the inspection image to the first autoencoder to output a first code that represents a first pixelated image. The method may also include inputting the design layout data to the second autoencoder to output a second code that represents a second pixelated image. The method may further include determining a first pixelated image, in which each pixel of the first pixelated image represents a difference value between a first value associated with a first pixel in the first pixelated image and a second value associated with a second pixel in the second pixelated image. The first pixel and the second pixel may be co-located. The method may further include inputting the inspection image to the third autoencoder to output a third code that represents a third pixelated image. The method may further include inputting the design layout data to the fourth autoencoder to output a fourth code that represents a fourth pixelated image. The method may further include determining a second pixelated image, in which each pixel of the second pixelated image represents a difference value between a third value associated with a third pixel in the third pixelated image and a fourth value associated with a fourth pixel in the fourth pixelated image. The third pixel and the fourth pixel may be co-located. The method may further include determining the defect map as a combined image, in which each pixel of the combined image has a value generated based on a product of a difference value associated with a pixel in the first pixelated image multiplied by a difference value associated with a pixel in the second pixelated image.

By way of example, with reference to FIGS. 5 and 9, the trained machine learning model may include first XAE 1008 and second XAE 1010. First XAE 1008 may include a first autoencoder (e.g., including first encoder 506 of FIG. 5) and a second autoencoder (e.g., including second encoder 508 of FIG. 5). Second XAE 1010 may include a third autoencoder and a fourth encoder. Inspection image 1004 may be inputted to the first autoencoder of first XAE 1008 to generate the first code (e.g., first code 510 of FIG. 5), and design layout data 1006 may be inputted to the second autoencoder of first XAE 1008 to generate the second code (e.g., second code 512 of FIG. 5). Based on the first code and the second code, first code difference 1009 (e.g., similar to code difference 511 of FIG. 5) may be generated and may be represented as the first pixelated image, such as in a manner described in association with FIG. 5 and Eq. (1).

Similarly, second XAE 1010 may include a third autoencoder and a fourth autoencoder. Second XAE 1010 may include a third autoencoder and a fourth encoder. Inspection image 1004 may be inputted to the third autoencoder of second XAE 1010 to generate the third code, and design layout data 1006 may be inputted to the fourth autoencoder of second XAE 1010 to generate the fourth code. Based on the third code and the fourth code, second code difference 1011 may be generated and may be represented as the second pixelated image, such as in a manner described in association with FIG. 5 and Eq. (1).

The defect map may be determined as a combined image generated based on the first pixelated image and the second pixelated image. By way of example, with reference to Eq. (1) and assuming both the first pixelated image and the second pixelated image have 2×2 pixels, pixels of the combined image may be represented as P_{(x,y)}^{DM} in Eq. (11):

$${P}_{( x , y )}^{α} = \frac{1}{2} {( {P}_{( x , y )}^{A} - {P}_{( x , y )}^{B} )}^{2} , \{ x , y \} = \{ 0 , 1 \} \qquad Eq . ( 9 )$$

$${P}_{( x , y )}^{β} = \frac{1}{2} {( {P}_{( x , y )}^{C} - {P}_{( x , y )}^{D} )}^{2} , \{ x , y \} = \{ 0 , 1 \} \qquad Eq . ( 10 )$$

$${P}_{( x , y )}^{D M} ∼ {P}_{( x , y )}^{α} \cdot {P}_{( x , y )}^{β} , \{ x , y \} = \{ 0 , 1 \} \qquad Eq . ( 11 )$$

In Eq. (9), P_{(x,y)}^{α} represents a value associated with a pixel located at coordinate (x, y) in first code difference 1009. P_{(x,y)}^{A} represents a value (e.g., a grayscale-level value, an RGB value, or the like) associated with a pixel located at coordinate (x, y) in the first code. P_{(x,y)}^{B} represents a value (e.g., a grayscale-level value, an RGB value, or the like) associated with a pixel located at coordinate (x, y) in the second code. P_{(x,y)}^{A} and P_{(x,y)}^{B} may be of the same type of values. As shown in Eq. (9), P_{(x,y)}^{α} is an MSE determined based on P_{(x,y)}^{A} and P_{(x,y)}^{B}.

In Eq. (10), P_{(x,y)}^{β} represents a value associated with a pixel located at coordinate (x, y) in second code difference 1011. P_{(x,y)}^{C} represents a value (e.g., a grayscale-level value, an RGB value, or the like) associated with a pixel located at coordinate (x, y) in the third code. P_{(x,y)}^{D} represents a value (e.g., a grayscale-level value, an RGB value, or the like) associated with a pixel located at coordinate (x, y) in the fourth code. P_{(x,y)}^{C} and P_{(x,y)}^{D} may be of the same type of values. As shown in Eq. (10), P_{(x,y)}^{β} is an MSE determined based on P_{(x,y)}^{C} and P_{(x,y)}^{D}.

In Eq. (11), P_{(x,y)}^{DM} represents a value associated with a pixel located at coordinate (x, y) in the combined image (i.e., the outputted defect map). As shown in Eq. (11), P_{(x,y)}^{DM} is generated based on a product of P_{(x,y)}^{α} and P_{(x,y)}^{β}. In some embodiments, P_{(x,y)}^{DM} may be determined as the product of P_{(x,y)}^{α} and P_{(x,y)}^{β} (i.e., P_{(x,y)}^{DM}=P_{(x,y)}^{α}·P_{(x,y)}^{α}). In some embodiments, P_{(x,y)}^{DM} may be determined as a weighted product of P_{(x,y)}^{α} and P_{(x,y)}^{β} (i.e., P_{(x,y)}^{DM}=w_{(x,y)}·P_{(x,y)}^{α}·P_{(x,y)}^{β} where w_{(x,y)} represents a weight associated with a pixel located at coordinate (x, y) in the combined image). It should be noted that the manner of determining P_{(x,y)}^{DM} based on P_{(x,y)}^{α}·P_{(x,y)}^{β} may be various and are not limited to the examples described herein.

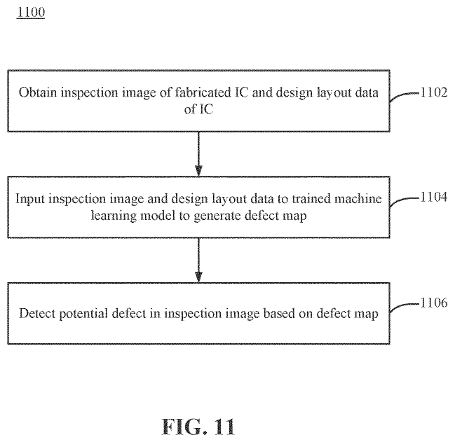

By way of example, FIG. 11 is a flowchart illustrating an example method 1100 for defect detection, consistent with some embodiments of the present disclosure. Method 1100 may be performed by a controller that may be coupled with a charged-particle beam tool (e.g., charged-particle beam inspection system 100) or an optical beam tool. For example, the controller may be controller 109 in FIG. 2. The controller may be programmed to implement method 1100.

At step 1102, the controller may obtain an inspection image (e.g., inspection image 1004 of FIG. 10) of a fabricated integrated circuit (IC) and design layout data (e.g., design layout data 1006 of FIG. 10) of the IC. In some embodiments, the design layout data may include an image rendered based on graphic design system (GDS) clip data of the IC.

At step 1104, the controller may input the inspection image and the design layout data to a trained machine learning model (e.g., trained machine learning model 1002 of FIG. 10) to generate a defect map (e.g., defect map 1016 of FIG. 10). The trained machine learning model may include a first cross autoencoder (e.g., first XAE 1008 of FIG. 10). The first cross autoencoder may include a first autoencoder configured to obtain the inspection image as input and a second autoencoder configured to obtain the design layout data as input.

In some embodiments, to generate the defect map, the controller may input the inspection image to the first autoencoder to output a first code that represents a first pixelated image. The controller may also input the design layout data to the second autoencoder to output a second code that represents a second pixelated image. The controller may further determine the defect map as a pixelated image (e.g., first code difference 1009). Each pixel of the defect map may represent a difference between a first value associated with a first pixel in the first pixelated image and a second value associated with a second pixel in the second pixelated image. The first pixel and the second pixel may be co-located.

At step 1106, the controller may detect a potential defect in the inspection image based on the defect map.

In some embodiments, the trained machine learning model of method 1100 may further include a second cross autoencoder (e.g., second XAE 1010 or third XAE 1012 of FIG. 10) different from the first cross autoencoder. The second cross autoencoder model may include a third autoencoder configured to obtain the inspection image as input and a fourth autoencoder configured to obtain the design layout data as input.

When the trained machine learning model includes the first cross autoencoder and the second autoencoder, to generate the defect map, the controller may input the inspection image to the first autoencoder to output a first code that represents a first pixelated image. The controller may also input the design layout data to the second autoencoder to output a second code that represents a second pixelated image. The controller may further determine a first pixelated image (e.g., first code difference 1009). Each pixel of the first pixelated image may represent a difference value (e.g., an MSE value P_{(x,y)}^{α} of Eq. (9)) between a first value (e.g., P_{(x,y)}^{A} of Eq. (9)) associated with a first pixel in the first pixelated image and a second value (e.g., P_{(x,y)}^{B} of Eq. (9)) associated with a second pixel in the second pixelated image. The first pixel and the second pixel may be co-located. The controller may further input the inspection image to the third autoencoder to output a third code that represents a third pixelated image. The controller may further input the design layout data to the fourth autoencoder to output a fourth code that represents a fourth pixelated image. The controller may then determine a second pixelated image. Each pixel of the second pixelated image may represent a difference value (e.g., an MSE value P_{(x,y)}^{β} of Eq. (10)) between a third value (e.g., P_{(x,y)}^{C} of Eq. (10)) associated with a third pixel in the third pixelated image and a fourth value (e.g., P_{(x,y)}^{D} of Eq. (10)) associated with a fourth pixel in the fourth pixelated image. The controller may then determine the defect map as a combine image. Each pixel of the combined image may have a value (e.g., P_{(x,y)}^{DM} of Eq. (11)) generated based on a product (e.g., P_{(x,y)}^{α}·P_{(x,y)}^{β} of Eq. (11)) of a difference value (e.g., P_{(x,y)}^{α} of Eq. (11)) associated with a pixel in the first pixelated image multiplied by a difference value (e.g., P_{(x,y)}^{β} of Eq. (11)) associated with a pixel in the second pixelated image.

A non-transitory computer readable medium may be provided that stores instructions for a processor (for example, processor of controller 109 of FIG. 1) to carry out image processing such as method 1000 of FIG. 10, method 1200 of FIG. 12, method 1300 of FIG. 13, data processing, database management, graphical display, operations of an image inspection apparatus or another imaging device, detecting a defect on a sample, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The embodiments can further be described using the following clauses:

1. A non-transitory computer-readable medium that stores a set of instructions that is executable by at least one processor of an apparatus to cause the apparatus to perform a method, the method comprising:
obtaining training data comprising an inspection image of a fabricated integrated circuit (IC) and design layout data of the IC; and
training a machine learning model using the training data, wherein
the machine learning model comprises a first autoencoder and a second autoencoder,
the first autoencoder comprises a first encoder and a first decoder,
the second autoencoder comprises a second encoder and a second decoder,
the second decoder is configured to obtain a first code outputted by the first encoder, and
the first decoder is configured to obtain a second code outputted by the second encoder.
   2. The non-transitory computer-readable medium of clause 1, wherein the design layout data comprises an image rendered based on graphic design system (GDS) clip data of the IC.
   3. The non-transitory computer-readable medium of clause 2, wherein the set of instructions that is executable by at least one processor of the apparatus to cause the apparatus to further perform: aligning the inspection image and the rendered image.
   4. The non-transitory computer-readable medium of any of clauses 1-3, wherein the set of instructions that is executable by at least one processor of the apparatus to cause the apparatus to further perform:
inputting the inspection image to the first encoder to output the first code, the first code representing a first pixelated image;
inputting the design layout data to the second encoder to output the second code, the second code representing a second pixelated image; and
determining a pixelated difference image, wherein each pixel of the pixelated difference image represents a difference between a first value associated with a first pixel in the first pixelated image and a second value associated with a second pixel in the second pixelated image.
   5. The non-transitory computer-readable medium of any of clauses 1-4, wherein a loss function for training the machine learning model comprises a first component representing a difference between a first code outputted by the first encoder and a second code outputted by the second encoder.
   6. The non-transitory computer-readable medium of clause 5, wherein the loss function further comprises a second component representing a difference between the inspection image and a decoded inspection image outputted by the first decoder, and a third component representing a difference between the design layout data and decoded design layout data outputted by the second decoder.
   7. The non-transitory computer-readable medium of clause 6, wherein the loss function is a sum of the first component, the second component, and the third component.
   8. The non-transitory computer-readable medium of any of clauses 6-7, wherein the set of instructions that is executable by at least one processor of the apparatus to cause the apparatus to further perform:
inputting the first code to the second decoder to output the decoded design layout data; and inputting the second code to the first decoder to output the decoded inspection image.
   9. The non-transitory computer-readable medium of any of clauses 5-8, wherein the first component further comprises a parameter, and wherein training the machine learning model using the training data comprises:
in response to the parameter being of a first value, training the machine learning model using a supervised learning technique; and
in response to the parameter being of a second value different from the first value, training the machine learning model using an unsupervised learning technique.
   10. A non-transitory computer-readable medium that stores a set of instructions that is executable by at least one processor of an apparatus to cause the apparatus to perform a method, the method comprising:
obtaining first data comprising a first inspection image of a fabricated first integrated circuit (IC) and first design layout data of the first IC;
training a first machine learning model using the first data;
obtaining second data comprising a second inspection image of a fabricated second IC and second design layout data of the second IC;
generating adjusted design layout data by adjusting a polygon of the second design layout data; and training a second machine learning model using the second inspection image and the adjusted design layout data.
   11. The non-transitory computer-readable medium of clause 10, wherein adjusting the polygon of the second design layout data comprises at least one of:
randomly moving the polygon in the second design layout data; or
randomly resizing the polygon in the second design layout data.
   12. The non-transitory computer-readable medium of any of clauses 10-11, wherein the first IC is the same as the second IC, the first inspection image is the same as the second inspection image, and the first design layout data is the same as the second design layout data.
   13. The non-transitory computer-readable medium of any of clauses 10-12, wherein the first design layout data comprises a first image rendered based on first graphic design system (GDS) clip data of the first IC, and the second design layout data comprises a second image rendered based on second GDS clip data of the second IC.
   14. The non-transitory computer-readable medium of clause 13, wherein the set of instructions that is executable by at least one processor of the apparatus to cause the apparatus to further perform:
aligning the first inspection image and the first rendered image; and
aligning the second inspection image and the second rendered image.
   15. The non-transitory computer-readable medium of any of clauses 10-14, wherein the first data comprises a first set of inspection images of fabricated ICs and a first set of design layout data of the fabricated ICs, each piece of the first set of design layout data corresponding to one of the first set of inspection images, and
the second data comprises a second set of inspection images of fabricated ICs and a second set of design layout data of the fabricated ICs, each piece of the second set of design layout data corresponding to one of the second set of inspection images.
   16. The non-transitory computer-readable medium of clause 15, wherein the first data is the same as the second data, the first set of inspection images is the same as the second set of inspection images, and the first set of design layout data is the same as the second set of design layout data.
   17. The non-transitory computer-readable medium of clause 15, wherein generating the adjusted design layout data by adjusting the polygon of the second design layout data comprises: generating the adjusted design layout data by adjusting a polygon of at least one piece of the second set of design layout data, wherein the at least one piece of the second set of design layout data comprises the second design layout data.
   18. The non-transitory computer-readable medium of any of clauses 10-17, wherein the first machine learning model comprises a first cross autoencoder, and the second machine learning model comprises a second cross autoencoder different from the first cross autoencoder.
   19. A non-transitory computer-readable medium that stores a set of instructions that is executable by at least one processor of an apparatus to cause the apparatus to perform a method, the method comprising:
obtaining an inspection image of a fabricated integrated circuit (IC) and design layout data of the IC; inputting the inspection image and the design layout data to a trained machine learning model to generate a defect map, wherein the trained machine learning model comprises a first cross autoencoder, and the first cross autoencoder comprises a first autoencoder configured to obtain the inspection image as input and a second autoencoder configured to obtain the design layout data as input; and
detecting a potential defect in the inspection image based on the defect map.
   20. The non-transitory computer-readable medium of clause 19, wherein the design layout data comprises an image rendered based on graphic design system (GDS) clip data of the IC.
   21. The non-transitory computer-readable medium of any of clauses 19-20, wherein inputting the inspection image and the design layout data to the trained machine learning model to generate the defect map comprises:
inputting the inspection image to the first autoencoder to output a first code, the first code representing a first pixelated image;
inputting the design layout data to the second autoencoder to output a second code, the second code representing a second pixelated image; and
determining the defect map as a pixelated image, wherein each pixel of the defect map represents a difference between a first value associated with a first pixel in the first pixelated image and a second value associated with a second pixel in the second pixelated image.
   22. The non-transitory computer-readable medium of any of clauses 19-21, wherein the trained machine learning model further comprises a second cross autoencoder different from the first cross autoencoder, and the second cross autoencoder model comprises a third autoencoder configured to obtain the inspection image as input and a fourth autoencoder configured to obtain the design layout data as input.
   23. The non-transitory computer-readable medium of clause 22, wherein inputting the inspection image and the design layout data to the trained machine learning model to generate the defect map comprises:
inputting the inspection image to the first autoencoder to output a first code, the first code representing a first pixelated image;
inputting the design layout data to the second autoencoder to output a second code, the second code representing a second pixelated image;
determining a first pixelated image, wherein each pixel of the first pixelated image represents a difference value between a first value associated with a first pixel in the first pixelated image and a second value associated with a second pixel in the second pixelated image;
inputting the inspection image to the third autoencoder to output a third code, the third code representing a third pixelated image;
inputting the design layout data to the fourth autoencoder to output a fourth code, the fourth code representing a fourth pixelated image;
determining a second pixelated image, wherein each pixel of the second pixelated image represents a difference value between a third value associated with a third pixel in the third pixelated image and a fourth value associated with a fourth pixel in the fourth pixelated image; and
determining the defect map as a combined image, wherein each pixel of the combined image has a value generated based on a product of a difference value associated with a pixel in the first pixelated image multiplied by a difference value associated with a pixel in the second pixelated image.
   24. A system, comprising:
an image inspection apparatus configured to scan a sample and generate an inspection image of an integrated circuit (IC) fabricated on the sample; and
a controller including circuitry, configured to:
obtain training data comprising the inspection image of the IC and design layout data of the IC; and
train a machine learning model using the training data, wherein
the machine learning model comprises a first autoencoder and a second autoencoder,
the first autoencoder comprises a first encoder and a first decoder,
the second autoencoder comprises a second encoder and a second decoder,
the second decoder is configured to obtain a first code outputted by the first encoder, and
the first decoder is configured to obtain a second code outputted by the second encoder.
   25. The system of clause 24, wherein the design layout data comprises an image rendered based on graphic design system (GDS) clip data of the IC.
   26. The system of clause 25, wherein the controller includes circuitry further configured to: align the inspection image and the rendered image.
   27. The system of any of clauses 24-26, wherein the controller includes circuitry further configured to:
input the inspection image to the first encoder to output the first code, the first code representing a first pixelated image;
input the design layout data to the second encoder to output the second code, the second code representing a second pixelated image; and
determine a pixelated difference image, wherein each pixel of the pixelated difference image represents a difference between a first value associated with a first pixel in the first pixelated image and a second value associated with a second pixel in the second pixelated image.
   28. The system of any of clauses 24-27, wherein a loss function for training the machine learning model comprises a first component representing a difference between a first code outputted by the first encoder and a second code outputted by the second encoder.
   29. The system of clause 28, wherein the loss function further comprises a second component representing a difference between the inspection image and a decoded inspection image outputted by the first decoder, and a third component representing a difference between the design layout data and decoded design layout data outputted by the second decoder.
   30. The system of clause 29, wherein the loss function is a sum of the first component, the second component, and the third component.
   31. The system of any of clauses 29-30, wherein the controller includes circuitry further configured to:
input the first code to the second decoder to output the decoded design layout data; and
input the second code to the first decoder to output the decoded inspection image.
   32. The system of any of clauses 28-31, wherein the first component further comprises a parameter, and wherein the controller includes circuitry further configured to:
in response to the parameter being of a first value, train the machine learning model using a supervised learning technique; and
in response to the parameter being of a second value different from the first value, train the machine learning model using an unsupervised learning technique.
   33. A system, comprising:
an image inspection apparatus configured to scan a sample and generate an inspection image of an integrated circuit (IC) fabricated on the sample; and
a controller including circuitry, configured to:
obtain first data comprising a first inspection image of a fabricated first IC and first design layout data of the first IC;
train a first machine learning model using the first data;
obtain second data comprising a second inspection image of a fabricated second IC and second design layout data of the second IC;
generate adjusted design layout data by adjusting a polygon of the second design layout data; and train a second machine learning model using the second inspection image and the adjusted design layout data.
   34. The system of clause 33, wherein the circuitry configured to generate the adjusted design layout data by adjusting the polygon of the second design layout data if further configured to: perform at least one of:
generating the adjusted design layout data by randomly moving the polygon in the second design layout data; or
generating the adjusted design layout data by randomly resizing the polygon in the second design layout data.
   35. The system of any of clauses 33-34, wherein the first IC is the same as the second IC, the first inspection image is the same as the second inspection image, and the first design layout data is the same as the second design layout data.
   36. The system of any of clauses 33-35, wherein the first design layout data comprises a first image rendered based on first graphic design system (GDS) clip data of the first IC, and the second design layout data comprises a second image rendered based on second GDS clip data of the second IC.
   37. The system of clause 36, wherein the controller includes circuitry further configured to: align the first inspection image and the first rendered image; and align the second inspection image and the second rendered image.
   38. The system of any of clauses 33-37, wherein the first data comprises a first set of inspection images of fabricated ICs and a first set of design layout data of the fabricated ICs, each piece of the first set of design layout data corresponding to one of the first set of inspection images, and
the second data comprises a second set of inspection images of fabricated ICs and a second set of design layout data of the fabricated ICs, each piece of the second set of design layout data corresponding to one of the second set of inspection images.
   39. The system of clause 38, wherein the first data is the same as the second data, the first set of inspection images is the same as the second set of inspection images, and the first set of design layout data is the same as the second set of design layout data.
   40. The system of clause 38, wherein the circuitry configured to generate the adjusted design layout data by adjusting the polygon of the second design layout data is further configured to:
generate the adjusted design layout data by adjusting a polygon of at least one piece of the second set of design layout data, wherein the at least one piece of the second set of design layout data comprises the second design layout data.
   41. The system of any of clauses 33-40, wherein the first machine learning model comprises a first cross autoencoder, and the second machine learning model comprises a second cross autoencoder different from the first cross autoencoder.
   42. A system, comprising:
an image inspection apparatus configured to scan a sample and generate an inspection image of an integrated circuit (IC) fabricated on the sample; and
a controller including circuitry, configured to:
obtain the inspection image of the IC and design layout data of the IC;
input the inspection image and the design layout data to a trained machine learning model to generate a defect map, wherein the trained machine learning model comprises a first cross autoencoder, and the first cross autoencoder comprises a first autoencoder configured to obtain the inspection image as input and a second autoencoder configured to obtain the design layout data as input; and detect a potential defect in the inspection image based on the defect map.
   43. The system of clause 42, wherein the design layout data comprises an image rendered based on graphic design system (GDS) clip data of the IC.
   44. The system of any of clauses 42-43, wherein inputting the inspection image and the design layout data to the trained machine learning model to generate the defect map comprises:
inputting the inspection image to the first autoencoder to output a first code, the first code representing a first pixelated image;
inputting the design layout data to the second autoencoder to output a second code, the second code representing a second pixelated image; and
determining the defect map as a pixelated image, wherein each pixel of the defect map represents a difference between a first value associated with a first pixel in the first pixelated image and a second value associated with a second pixel in the second pixelated image.
   45. The system of any of clauses 42-44, wherein the trained machine learning model further comprises a second cross autoencoder different from the first cross autoencoder, and the second cross autoencoder model comprises a third autoencoder configured to obtain the inspection image as input and a fourth autoencoder configured to obtain the design layout data as input.
   46. The system of clause 45, wherein inputting the inspection image and the design layout data to the trained machine learning model to generate the defect map comprises:
inputting the inspection image to the first autoencoder to output a first code, the first code representing a first pixelated image;
inputting the design layout data to the second autoencoder to output a second code, the second code representing a second pixelated image;
determining a first pixelated image, wherein each pixel of the first pixelated image represents a difference value between a first value associated with a first pixel in the first pixelated image and a second value associated with a second pixel in the second pixelated image;
inputting the inspection image to the third autoencoder to output a third code, the third code representing a third pixelated image;
inputting the design layout data to the fourth autoencoder to output a fourth code, the fourth code representing a fourth pixelated image;
determining a second pixelated image, wherein each pixel of the second pixelated image represents a difference value between a third value associated with a third pixel in the third pixelated image and a fourth value associated with a fourth pixel in the fourth pixelated image; and
determining the defect map as a combined image, wherein each pixel of the combined image has a value generated based on a product of a difference value associated with a pixel in the first pixelated image multiplied by a difference value associated with a pixel in the second pixelated image.
   47. A computer-implemented method of training a machine learning model for defect detection, the method comprising:
obtaining training data comprising an inspection image of a fabricated integrated circuit (IC) and design layout data of the IC; and
training a machine learning model using the training data, wherein
the machine learning model comprises a first autoencoder and a second autoencoder,
the first autoencoder comprises a first encoder and a first decoder,
the second autoencoder comprises a second encoder and a second decoder,
the second decoder is configured to obtain a first code outputted by the first encoder, and
the first decoder is configured to obtain a second code outputted by the second encoder.
   48. The computer-implemented method of clause 47, wherein the design layout data comprises an image rendered based on graphic design system (GDS) clip data of the IC.
   49. The computer-implemented method of clause 48, further comprising:
aligning the inspection image and the rendered image.
   50. The computer-implemented method of any of clauses 47-49, further comprising:
inputting the inspection image to the first encoder to output the first code, the first code representing a first pixelated image;
inputting the design layout data to the second encoder to output the second code, the second code representing a second pixelated image; and
determining a pixelated difference image, wherein each pixel of the pixelated difference image represents a difference between a first value associated with a first pixel in the first pixelated image and a second value associated with a second pixel in the second pixelated image.
   51. The computer-implemented method of any of clauses 47-50, wherein a loss function for training the machine learning model comprises a first component representing a difference between a first code outputted by the first encoder and a second code outputted by the second encoder.
   52. The computer-implemented method of clause 51, wherein the loss function further comprises a second component representing a difference between the inspection image and a decoded inspection image outputted by the first decoder, and a third component representing a difference between the design layout data and decoded design layout data outputted by the second decoder.
   53. The computer-implemented method of clause 52, wherein the loss function is a sum of the first component, the second component, and the third component.
   54. The computer-implemented method of any of clauses 52-53, further comprising:
inputting the first code to the second decoder to output the decoded design layout data; and
inputting the second code to the first decoder to output the decoded inspection image.
   55. The computer-implemented method of any of clauses 51-54, wherein the first component further comprises a parameter, and wherein training the machine learning model using the training data comprises:
in response to the parameter being of a first value, training the machine learning model using a supervised learning technique; and
in response to the parameter being of a second value different from the first value, training the machine learning model using an unsupervised learning technique.
   56. A computer-implemented method of training a plurality of machine learning models for defect detection, the method comprising:
obtaining first data comprising a first inspection image of a fabricated first integrated circuit (IC) and first design layout data of the first IC;
training a first machine learning model using the first data;
obtaining second data comprising a second inspection image of a fabricated second IC and second design layout data of the second IC;
generating adjusted design layout data by adjusting a polygon of the second design layout data; and training a second machine learning model using the second inspection image and the adjusted design layout data.
   57. The computer-implemented method of clause 56, wherein adjusting the polygon of the second design layout data comprises at least one of:
randomly moving the polygon in the second design layout data; or
randomly resizing the polygon in the second design layout data.
   58. The computer-implemented method of any of clauses 56-57, wherein the first IC is the same as the second IC, the first inspection image is the same as the second inspection image, and the first design layout data is the same as the second design layout data.
   59. The computer-implemented method of any of clauses 56-58, wherein the first design layout data comprises a first image rendered based on first graphic design system (GDS) clip data of the first IC, and the second design layout data comprises a second image rendered based on second GDS clip data of the second IC.
   60. The computer-implemented method of clause 59, further comprising:
aligning the first inspection image and the first rendered image; and
aligning the second inspection image and the second rendered image.
   61. The computer-implemented method of any of clauses 56-60, wherein the first data comprises a first set of inspection images of fabricated ICs and a first set of design layout data of the fabricated ICs, each piece of the first set of design layout data corresponding to one of the first set of inspection images, and
the second data comprises a second set of inspection images of fabricated ICs and a second set of design layout data of the fabricated ICs, each piece of the second set of design layout data corresponding to one of the second set of inspection images.
   62. The computer-implemented method of clause 61, wherein the first data is the same as the second data, the first set of inspection images is the same as the second set of inspection images, and the first set of design layout data is the same as the second set of design layout data.
   63. The computer-implemented method of clause 61, wherein generating the adjusted design layout data by adjusting the polygon of the second design layout data comprises:
generating the adjusted design layout data by adjusting a polygon of at least one piece of the second set of design layout data, wherein the at least one piece of the second set of design layout data comprises the second design layout data.
   64. The computer-implemented method of any of clauses 56-63, wherein the first machine learning model comprises a first cross autoencoder, and the second machine learning model comprises a second cross autoencoder different from the first cross autoencoder.
   65. A computer-implemented method of defect detection, the method comprising:
obtaining an inspection image of a fabricated integrated circuit (IC) and design layout data of the IC; inputting the inspection image and the design layout data to a trained machine learning model to generate a defect map, wherein the trained machine learning model comprises a first cross autoencoder, and the first cross autoencoder comprises a first autoencoder configured to obtain the inspection image as input and a second autoencoder configured to obtain the design layout data as input; and
detecting a potential defect in the inspection image based on the defect map.
   66. The computer-implemented method of clause 65, wherein the design layout data comprises an image rendered based on graphic design system (GDS) clip data of the IC.
   67. The computer-implemented method of any of clauses 65-66, wherein inputting the inspection image and the design layout data to the trained machine learning model to generate the defect map comprises:
inputting the inspection image to the first autoencoder to output a first code, the first code representing a first pixelated image;
inputting the design layout data to the second autoencoder to output a second code, the second code representing a second pixelated image; and
determining the defect map as a pixelated image, wherein each pixel of the defect map represents a difference between a first value associated with a first pixel in the first pixelated image and a second value associated with a second pixel in the second pixelated image.
   68. The computer-implemented method of any of clauses 65-67, wherein the trained machine learning model further comprises a second cross autoencoder different from the first cross autoencoder, and the second cross autoencoder model comprises a third autoencoder configured to obtain the inspection image as input and a fourth autoencoder configured to obtain the design layout data as input.
   69. The computer-implemented method of clause 68, wherein inputting the inspection image and the design layout data to the trained machine learning model to generate the defect map comprises: inputting the inspection image to the first autoencoder to output a first code, the first code representing a first pixelated image;
inputting the design layout data to the second autoencoder to output a second code, the second code representing a second pixelated image;
determining a first pixelated image, wherein each pixel of the first pixelated image represents a difference value between a first value associated with a first pixel in the first pixelated image and a second value associated with a second pixel in the second pixelated image;
inputting the inspection image to the third autoencoder to output a third code, the third code representing a third pixelated image;
inputting the design layout data to the fourth autoencoder to output a fourth code, the fourth code representing a fourth pixelated image;
determining a second pixelated image, wherein each pixel of the second pixelated image represents a difference value between a third value associated with a third pixel in the third pixelated image and a fourth value associated with a fourth pixel in the fourth pixelated image; and
determining the defect map as a combined image, wherein each pixel of the combined image has a value generated based on a product of a difference value associated with a pixel in the first pixelated image multiplied by a difference value associated with a pixel in the second pixelated image.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

1. A non-transitory computer-readable medium that stores a set of instructions that is executable by at least one processor of an apparatus to cause the apparatus to perform a method, the method comprising:
obtaining training data comprising an inspection image of a fabricated integrated circuit (IC) and design layout data of the IC; and
training a machine learning model using the training data, wherein
the machine learning model comprises a first autoencoder and a second autoencoder,
the first autoencoder comprises a first encoder and a first decoder,
the second autoencoder comprises a second encoder and a second decoder,
the second decoder is configured to obtain a first code outputted by the first encoder, and
the first decoder is configured to obtain a second code outputted by the second encoder.

2. The non-transitory computer-readable medium of claim 1, wherein the design layout data comprises an image rendered based on graphic design system (GDS) clip data of the IC.

3. The non-transitory computer-readable medium of claim 2, wherein the set of instructions that is executable by at least one processor of the apparatus to cause the apparatus to further perform:
aligning the inspection image and the rendered image.

4. The non-transitory computer-readable medium of claim 1, wherein the set of instructions that is executable by at least one processor of the apparatus to cause the apparatus to further perform:
inputting the inspection image to the first encoder to output the first code, the first code representing a first pixelated image;
inputting the design layout data to the second encoder to output the second code, the second code representing a second pixelated image; and
determining a pixelated difference image, wherein each pixel of the pixelated difference image represents a difference between a first value associated with a first pixel in the first pixelated image and a second value associated with a second pixel in the second pixelated image.

5. The non-transitory computer-readable medium of claim 1, wherein a loss function for training the machine learning model comprises a first component representing a difference between a first code outputted by the first encoder and a second code outputted by the second encoder.

6. The non-transitory computer-readable medium of claim 5, wherein the loss function further comprises a second component representing a difference between the inspection image and a decoded inspection image outputted by the first decoder, and a third component representing a difference between the design layout data and decoded design layout data outputted by the second decoder.

7. The non-transitory computer-readable medium of claim 6, wherein the loss function is a sum of the first component, the second component, and the third component.

8. The non-transitory computer-readable medium of claim 6, wherein the set of instructions that is executable by at least one processor of the apparatus to cause the apparatus to further perform:
inputting the first code to the second decoder to output the decoded design layout data; and
inputting the second code to the first decoder to output the decoded inspection image.

9. The non-transitory computer-readable medium of claim 5, wherein the first component further comprises a parameter, and wherein training the machine learning model using the training data comprises:
in response to the parameter being of a first value, training the machine learning model using a supervised learning technique; and
in response to the parameter being of a second value different from the first value, training the machine learning model using an unsupervised learning technique.

10. A system, comprising:
an image inspection apparatus configured to scan a sample and generate an inspection image of an integrated circuit (IC) fabricated on the sample; and
a controller including circuitry, configured to:
obtain training data comprising the inspection image of the IC and design layout data of the IC; and
train a machine learning model using the training data, wherein
the machine learning model comprises a first autoencoder and a second autoencoder,
the first autoencoder comprises a first encoder and a first decoder,
the second autoencoder comprises a second encoder and a second decoder,
the second decoder is configured to obtain a first code outputted by the first encoder, and
the first decoder is configured to obtain a second code outputted by the second encoder.

11. The system of claim 10, wherein the design layout data comprises an image rendered based on graphic design system (GDS) clip data of the IC.

12. The system of claim 11, wherein the controller includes circuitry further configured to:
align the inspection image and the rendered image.

13. The system of claim 10, wherein the controller includes circuitry further configured to:
input the inspection image to the first encoder to output the first code, the first code representing a first pixelated image;
input the design layout data to the second encoder to output the second code, the second code representing a second pixelated image; and
determine a pixelated difference image, wherein each pixel of the pixelated difference image represents a difference between a first value associated with a first pixel in the first pixelated image and a second value associated with a second pixel in the second pixelated image.

14. The system of claim 10, wherein a loss function for training the machine learning model comprises a first component representing a difference between a first code outputted by the first encoder and a second code outputted by the second encoder.

15. The system of claim 14, wherein the loss function further comprises a second component representing a difference between the inspection image and a decoded inspection image outputted by the first decoder, and a third component representing a difference between the design layout data and decoded design layout data outputted by the second decoder.

16. A computer-implemented method of training a machine learning model for defect detection, the method comprising:
obtaining training data comprising an inspection image of a fabricated integrated circuit (IC) and design layout data of the IC; and
training a machine learning model using the training data, wherein
the machine learning model comprises a first autoencoder and a second autoencoder,
the first autoencoder comprises a first encoder and a first decoder,
the second autoencoder comprises a second encoder and a second decoder,
the second decoder is configured to obtain a first code outputted by the first encoder, and
the first decoder is configured to obtain a second code outputted by the second encoder.

17. The computer-implemented method of claim 16, wherein the design layout data comprises an image rendered based on graphic design system (GDS) clip data of the IC.

18. The computer-implemented method of claim 17, further comprising:
aligning the inspection image and the rendered image.

19. The computer-implemented method of claim 16, further comprising:
inputting the inspection image to the first encoder to output the first code, the first code representing a first pixelated image;
inputting the design layout data to the second encoder to output the second code, the second code representing a second pixelated image; and
determining a pixelated difference image, wherein each pixel of the pixelated difference image represents a difference between a first value associated with a first pixel in the first pixelated image and a second value associated with a second pixel in the second pixelated image.

20. The computer-implemented method of claim 16, wherein a loss function for training the machine learning model comprises a first component representing a difference between a first code outputted by the first encoder and a second code outputted by the second encoder.
